(19) United States
(12) Patent Application Publication
(10) Pub. No.: US 2026/0107663 A1
(43) Pub. Date: Apr. 16, 2026

(54) ADHESIVE MEMBER OF DISPLAY DEVICE, ELECTRONIC DEVICE HAVING THE SAME, AND METHOD PROVIDING THE SAME

(71) Applicant: Samsung Display Co., LTD., Yongin-si (KR)

(72) Inventor: Se Dae KI, Yongin-si (KR)

(21) Appl. No.: 19/223,362

(22) Filed: May 30, 2025

(30) Foreign Application Priority Data
Oct. 15, 2024 (KR) 10-2024-0140167

(51) Int. Cl. H10K 59/80; H10K 59/12

(52) U.S. Cl. CPC H10K 59/8722; H10K 59/1201; H10K 59/873

(57) ABSTRACT

A display device includes a substrate including a display area and a non-display area adjacent to each other, a transistor layer in the display area, a light emitting element layer in the display area and electrically connected to the transistor layer, and an encapsulation layer on the light emitting element layer and in the non-display area, an auxiliary pattern which is on the encapsulation layer in the non-display area, and spaced apart from the display area, and an adhesive layer on the encapsulation layer and the auxiliary pattern.

This application claims priority to Korean Patent Application No. 10-2024-0140167 filed on October 15, 2024, and all the benefits accruing therefrom under 35 U.S.C. 119, the contents of which in its entirety are incorporated herein by reference.

### BACKGROUND

### 1. Field

The present disclosure relates to an electronic device. More particularly, the present disclosure relates to a display device capable of preventing overflow of a material for providing an adhesive layer, an electronic device having the same and a method of providing the same.

### 2. Description of the Related Art

Organic light emitting diode displays have self-luminous characteristics and, unlike liquid crystal displays, do not require a separate light source, so their thickness and weight may be reduced. Also, organic light emitting diode displays exhibit high-quality characteristics such as low power consumption, high brightness, and high response speed, and are thus attracting attention as next-generation display devices for TVs, monitors, and portable electronic devices.

### SUMMARY

The present disclosure provides an adhesive member of a display device, an electronic device having the same, and a method of providing the same, each of which a flow of a material providing the adhesive member may be controlled to reduce or effectively prevent overflow of such material.

According to an embodiment of the present disclosure for achieving the above object, a display device includes a substrate, a transistor layer on the substrate, a light emitting element layer on the transistor layer, an encapsulation layer on the light emitting element layer, an auxiliary layer disposed on the encapsulation layer in a non-display area of the substrate, and an adhesive layer on the encapsulation layer and the auxiliary layer.

According to an embodiment of the present disclosure for achieving the above object, in a vehicle includes a display device, where the display device includes, a substrate, a transistor layer on the substrate, a light emitting element layer on the transistor layer, an encapsulation layer on the light emitting element layer, an auxiliary layer disposed on the encapsulation layer in a non-display area of the substrate, and an adhesive layer on the encapsulation layer and the auxiliary layer.

According to an embodiment of the present disclosure for achieving the above object, a method for manufacturing a display device includes forming a transistor layer on a substrate, the forming a light emitting element layer on the transistor layer, the forming an encapsulation layer on the light emitting element layer, the forming a first adhesive layer surrounding a display area of the substrate on the encapsulation layer in a non-display area of the substrate, the curing the first adhesive layer, the forming a second adhesive layer on the encapsulation layer within an area surrounded by the first adhesive layer, and the curing the second adhesive layer.

According to the display device, vehicle, and method for manufacturing the display device according to the present disclosure, overflow of the adhesive layer may be prevented.

For example, the display device of an embodiment includes an auxiliary layer formed of the same material as the sensor electrode and disposed at the edge of the substrate, so that overflow of the adhesive layer may be prevented by the auxiliary layer.

In addition, when manufacturing the display device, since the first adhesive layer is first formed at the edge of the substrate and then the second adhesive layer is formed, spreading of the second adhesive layer may be prevented by the first adhesive layer and the auxiliary layer.

The effects of the present disclosure are not limited to the above-described effects and other effects which are not described herein will become apparent to those skilled in the art from the following description.

### BRIEF DESCRIPTION OF THE DRAWINGS

The above and other advantages and features of this disclosure will become more apparent by describing in further detail embodiments thereof with reference to the accompanying drawings, in which:

FIG. 1 is a perspective view illustrating a display device according to an embodiment.

FIG. 2 is a plan view illustrating a display panel according to an embodiment.

FIG. 3 is a cross-sectional view of a display device according to an embodiment of the present disclosure along the line I-I’ of FIG. 2.

FIG. 4 is a cross-sectional view of a display device according to an embodiment of the present invention along the line I-I’ of FIG. 2.

FIG. 5 is a cross-sectional view of a display device according to an embodiment of the present invention along the line I-I’ of FIG. 2.

FIG. 6 is a cross-sectional view of a display device according to an embodiment of the present invention along the line I-I’ of FIG. 2.

FIG. 7 is a cross-sectional view of a display device according to an embodiment of the present invention along the line I-I’ of FIG. 2.

FIG. 8 is a cross-sectional view of a display device according to an embodiment of the present invention along the line I-I’ of FIG. 2.

FIG. 9 is a cross-sectional view of a display device according to an embodiment of the present invention along the line I-I’ of FIG. 2.

FIG. 10 is a cross-sectional view of a display device according to an embodiment of the present invention along the line I-I’ of FIG. 2.

FIGS. 11, FIG. 12, FIG. 13, FIG. 14, FIG. 15, FIG. 16, FIG. 17, FIG. 18, and FIG. 19 are various plan view and cross-sectional view drawings to illustrate a method of providing a display device according to an embodiment.

FIG. 20 is an exemplary drawing showing an instrument panel and center fascia of a vehicle including a display device according to an embodiment.

FIG. 21 is a block diagram of an electronic device according to an embodiment.

FIGS. 22 and 23 are schematic diagrams of electronic devices according to various embodiments.

### DETAILED DESCRIPTION

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being related to another element such as being “on” another layer or substrate, it can be directly on the other layer or substrate, or intervening layers may also be present. In contrast, when a layer is referred to as being related to another element such as being “directly on” another layer or substrate, no intervening layer is present.

The same reference numbers indicate the same components throughout the specification. Within the Figures and the text of the disclosure, a reference number indicating a singular form of an element may also be used to reference a plurality of the element. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described with reference to the accompanying drawings.

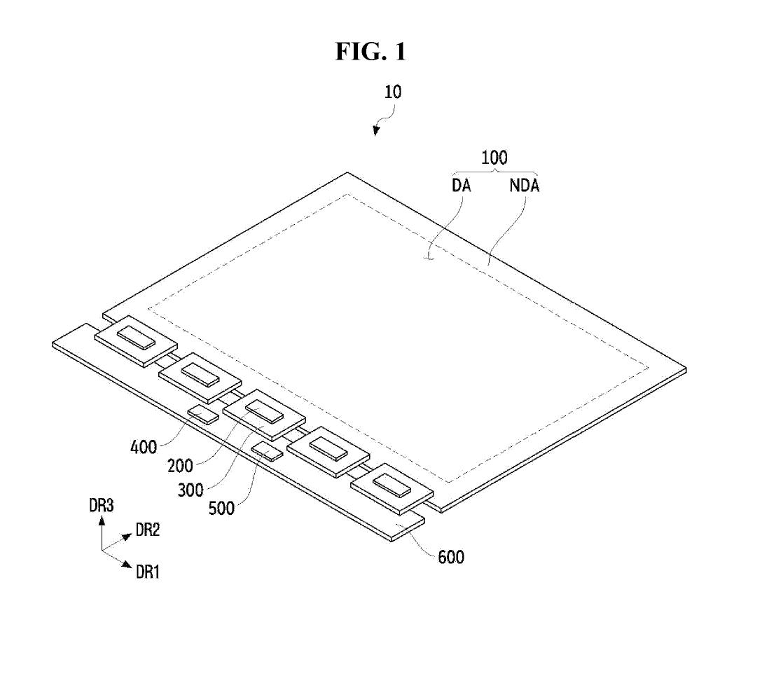

FIG. 1 is a perspective view illustrating a display device 10 according to an embodiment.

Referring to FIG. 1, a display device 10 is an electronic device for displaying video images or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and the internet of things (IOT).

The display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the display device 10 is described with emphasis on an organic light emitting display device, but the present disclosure is not limited thereto.

The display device 10 includes a display panel 100, a plurality of source driving circuits 200, a plurality of flexible circuit boards 300, a timing control circuit 400, a power supply circuit 500, and a circuit board 600.

The display panel 100 may be formed (or provided) as a rectangular planar element having a long side extended in a first direction DR1, and a short side extended in a second direction DR2 intersecting the first direction DR1. A plane may be defined by the first direction DR1 and the second direction DR2 crossing each other, and a view along a direction normal to such plane may define a plan view. In the plan view, a corner where the long side in the first direction DR1 and the short side in the second direction DR2 meet may be formed rounded to have a predetermined curvature or formed at a right angle. The plane shape (e.g., planar shape) of the display panel 100 is not limited to a rectilinear shape such as a square and may be formed in another polygonal, circular or oval shape. The display panel 100 may be formed flat (e.g., in a single plane) but is not limited thereto. For example, the display panel 100 may include a curved portion formed at the left and right ends opposite to each other along one or both of the first direction DR1 and the second direction DR2, and having a constant curvature or a varying curvature along a thickness direction. Additionally, the display panel 100 may be formed flexibly to be bent, curved, folded or rolled.

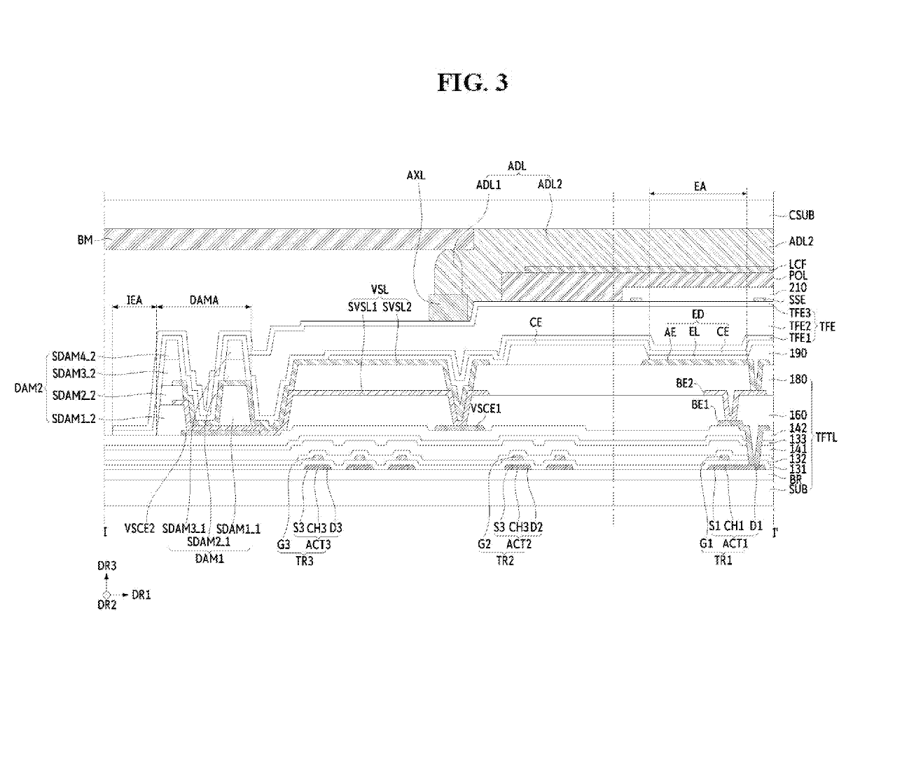

The display panel 100 may include a display area DA which displays an image and a non-display area NDA which is adjacent to the display area DA, such as being disposed extended along or around the display area DA in the plan view. A substrate of the display panel 100 (e.g., SUB in FIG. 3) may include the display area DA and the non-display area NDA. That is, various elements or layers of the display device 10 may include planar areas corresponding to the display area DA and the non-display area NDA described above.

The display area DA may occupy most of the area of the display panel 100 (e.g., the planar area). The display area DA may be disposed at the center of the display panel 100, such as being spaced apart from outer edges of the display panel 100. A pixel PX provided in plural including plurality of pixels PX may be disposed in the display area DA to display an image.

The non-display area NDA may be an area which does not display an image. The non-display area NDA may be an edge area of the display panel 100. The non-display area NDA may be an outer area of the display area DA. The non-display area NDA may be disposed to surround the display area DA in the plan view.

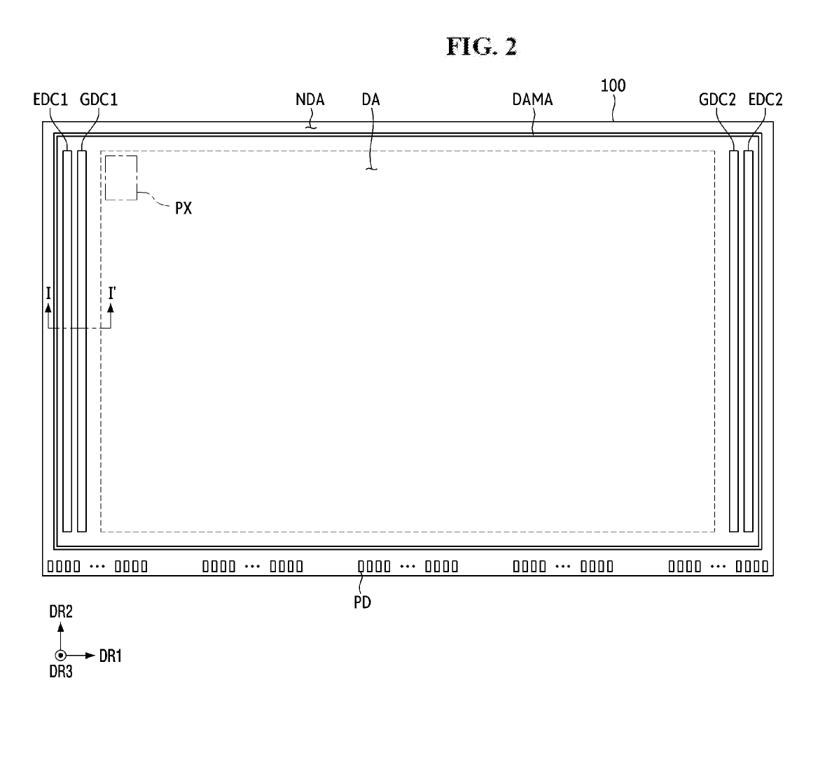

In the non-display area NDA, display pads PD (in FIG. 2) may be disposed to connect (e.g., electrically and/or physically) the display panel 100 to a plurality of flexible circuit boards 300. The display pads PD (in FIG. 2) may be disposed at or along one edge of the display panel 100.

Each of the source driving circuits 200 may be formed as an integrated circuit (IC) and attached to a corresponding flexible circuit board 300 to form a part thereof, but the embodiment of the present disclosure is not limited thereto. Each of the source driving circuits 200 may be attached to the display panel 100 by a chip on glass (COG) method, a chip on plastic (COP) method, or an ultrasonic bonding method to form a part of the display panel 100.

Each of the plurality of flexible circuit boards 300 may be disposed on display pads PD (in FIG. 2) which are disposed on one edge of the display panel 100. Each of the plurality of flexible circuit boards 300 may be attached to display pads PD (in FIG. 2) using a conductive adhesive such as an anisotropic conductive film. As a result, the plurality of flexible circuit boards 300 may be electrically connected to signal lines of the display panel 100 at the display pads PD thereof. The plurality of flexible circuit boards 300 may be a flexible film such as a flexible printed circuit board or a chip on film.

The timing control circuit 400 may generate timing control signals as electrical signal to control the timing of the gate driving circuit (GDC1, GDC2 in FIG. 2), the light emitting driving circuit (EDC1, EDC2 in FIG. 2), and the source driving circuit 200. The power supply circuit 500 may generate a plurality of power voltages as electrical signals for driving the display panel 100 according to an input power input from the outside (e.g., the outside of the display device 10. Each of the timing control circuit 400 and the power supply circuit 500 may be formed as an integrated circuit IC and attached to the circuit board 600.

The circuit board 600 may be connected to one side of each of a plurality of flexible circuit boards 300, such as sides furthest from the display area DA. The circuit board 600 may be a rigid printed circuit board.

FIG. 2 is a plan view illustrating a display panel 100 according to an embodiment.

Referring to FIG. 2, the display panel 100 may include display pads PD, a first gate driving circuit GDC1, a first light emitting driving circuit EDC1, a second gate driving circuit GDC2, a second light emitting driving circuit EDC2, and a dam area DAMA.

A display pad PD provided in plural including the display pads PD may be arranged along one edge of the display panel 100. The display pads PD may be divided into a plurality of groups. When the display device 10 includes five flexible circuit boards 300 as shown in FIG. 1, the display pads PD may be divided into five groups of display pad. The display pads PD of each of the plurality of groups may correspond one-to-one with bumps (not shown) of the corresponding flexible circuit board 300. Therefore, the display pads PD of each of the plurality of groups may be electrically connected to the corresponding flexible circuit board 300 at the bumps thereof.

Among the display pads PD, some of the display pads PD may be electrically connected to data lines DL (in FIG. 3) disposed in the display area DA. Among the display pads PD, others of the display pads PD may be variously electrically connected to a first gate driving circuit GDC1, a second gate driving circuit GDC2, a first light emitting driving circuit EDC1, and a second light emitting driving circuit EDC2.

The first gate driving circuit GDC1 and the second gate driving circuit GDC2 may be electrically connected to scan lines of the display area DA. The first gate driving circuit GDC1 may be disposed in a non-display area NDA of a first side (e.g., a left side in FIG. 2) of the display panel 100. The second gate driving circuit GDC2 may be disposed in a non-display area NDA of a second side (e.g., a right side in FIG. 2) of the display panel 100.

The first light emitting driving circuit EDC1 and the second light emitting driving circuit EDC2 may be electrically connected to the light emitting control lines of the display area DA. The first light emitting driving circuit EDC1 may be disposed in a non-display area NDA of a first side (e.g., a left side) of the display panel 100. The second light emitting driving circuit EDC2 may be disposed in a non-display area NDA of a second side (e.g., a right side) of the display panel 100.

The first gate driving circuit GDC1 may be disposed between the display area DA and the first light emitting driving circuit EDC1. The first gate driving circuit GDC1 may be disposed closer to the display area DA than the first light emitting driving circuit EDC1. Also, the first light emitting driving circuit EDC1 may be disposed closer to the first side edge of the display panel 100 than the first gate driving circuit GDC1.

The second gate driving circuit GDC2 may be disposed between the display area DA and the second light emitting driving circuit EDC2. The second gate driving circuit GDC2 may be disposed closer to the display area DA than the second light emitting driving circuit EDC2. Also, the second light emitting driving circuit EDC2 may be disposed closer to the second side edge of the display panel 100 than the second gate driving circuit GDC2.

The dam area DAMA may include at least one dam (DAM1, DAM2 in FIG. 3) to prevent the encapsulation organic layer (TFE2 in FIG. 3) from overflowing into the display pads PD. The dam area DAMA may be disposed to surround the display area DA.

FIG. 3 is a cross-sectional view of a display device 10 according to an embodiment of the present disclosure along the line I-I’ of FIG. 2.

Referring to FIG. 3, the substrate SUB may be made of (or include) an insulating material such as glass or polymer resin.

A transistor layer TFTL may be disposed on the substrate SUB, a light emitting element layer including a light emitting element ED and a bank 190 may be disposed on the transistor layer TFTL, and an encapsulation layer TFE may be disposed on the light emitting element layer.

A barrier film BR may be disposed on the substrate SUB. The barrier film BR may be a film to protect the thin film transistors and the light emitting layer EL from moisture penetrating through the substrate SUB which is vulnerable to moisture permeation. The barrier film BR may be made of a plurality of inorganic layers which are alternately laminated.

A pixel transistor TR1 of a pixel PX, a gate driving transistor TR2 of a gate driving circuit (e.g., GDC1), and a light emitting driving transistor TR3 of a light emitting driving circuit (e.g., EDC1) may be disposed on the barrier film BR. The pixel transistor TR1 may be disposed on the barrier film BR in a display area DA, and the gate driving transistor TR2 and the light emitting driving transistor TR3 may be disposed on the barrier film BR in a non-display area NDA. Referring to FIGS. 2 and 3, for example, a boundary between the display area DA and the non-display area NDA may be represented by a dotted line.

The pixel transistor TR1 may include a first active layer ACT1 and a first gate electrode G1. The gate driving transistor TR2 may include a second active layer ACT2 and a second gate electrode G2. The light emitting driving transistor TR3 may include a third active layer ACT3 and a third gate electrode G3.

A first active layer ACT1 of a pixel transistor TR1, a second active layer ACT2 of a gate driving transistor TR2, and a third active layer ACT3 of a light emitting driving transistor TR3 may be disposed on a barrier film BR. The first active layer ACT1 may include polycrystalline silicon, monocrystalline silicon, low-temperature polycrystalline silicon, or amorphous silicon. The second active layer ACT2 and the third active layer ACT3 may be made of the same material as the first active layer ACT1, such as being in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The first active layer ACT1 may include a first channel area CH1, a first source area S1, and a first drain area D1. The first source area S1 may be disposed on one side of the first channel area CH1, and the first drain area D1 may be disposed on the other side of the first channel area CH1.

The second active layer ACT2 may include a second channel area CH2, a second source area S2, and a second drain area D2. The second source area S2 may be disposed on one side of the second channel area CH2, and the second drain area D2 may be disposed on the other side of the second channel area CH2.

The third active layer ACT3 may include a third channel area CH3, a third source area S3, and a third drain area D3. The third source area S3 may be disposed on one side of the third channel area CH3, and the third drain area D3 may be disposed on the other side of the third channel area CH3.

A first gate insulating layer 131 may be disposed on the first active layer ACT1, the second active layer ACT2, and the third active layer ACT3.

A gate metal layer including gate electrodes may be disposed on the first gate insulating layer 131. For example, a first gate electrode G1 of a pixel transistor TR1, a second gate electrode G2 of a gate driving transistor TR2, and a third gate electrode G3 of a light emitting driving transistor TR3 may be disposed on the first gate insulating layer 131. The first gate electrode G1 may overlap with the first channel area CH1 of the first active layer ACT1, the second gate electrode G2 may overlap with the second channel area CH2 of the second active layer ACT2, and the third gate electrode G3 may overlap with the third channel area CH3 of the third active layer ACT3.

A second gate insulating layer 132 may be disposed on the gate metal layer. For example, a second gate insulating layer 132 may be disposed on the first gate electrode G1, the second gate electrode G2, and the third gate electrode G3.

A first interlayer insulating layer 141 may be disposed on the second gate insulating layer 132.

A third gate insulating layer 133 may be disposed on the first interlayer insulating layer 141.

A second interlayer insulating layer 142 may be disposed on the third gate insulating layer 133.

A first connection electrode layer including connection electrodes such as a first connection electrode BE1, a first power supply connection electrode VSCE1, and a second power supply connection electrode VSCE2 may be disposed on the second interlayer insulating layer 142. The first connection electrode BE1 may be connected to the first drain area D1 of the pixel transistor TR1 through a contact hole penetrating the second interlayer insulating layer 142, the third gate insulating layer 133, the first interlayer insulating layer 141, the second gate insulating layer 132, and the first gate insulating layer 131.

A first planarization layer 160 may be disposed on the first connection electrode BE1, the first power supply connection electrode VSCE1, and the second power supply connection electrode VSCE2.

A second connection electrode layer including connection electrodes such as a second connection electrode BE2 and a first sub-power supply line SVSL1 may be disposed on the first planarization layer 160. The second connection electrode BE2 may be connected to the first connection electrode BE1 through a contact hole penetrating the first planarization layer 160. The first sub-power supply line SVSL1 may be connected to the first power supply connection electrode VSCE1 through a contact hole penetrating the first planarization layer 160. Further, the first sub-power supply line SVSL1 may be connected to the second power supply connection electrode VSCE2 in the dam area DAMA.

A second planarization layer 180 may be disposed on the second connection electrode BE2 and the first sub-power supply line SVSL1.

The light emitting element ED and a second sub-power supply line SVSL2 may be disposed on the second planarization layer 180. For example, an anode electrode AE of the light emitting element ED and a second sub-power supply line SVSL2 may be disposed on the second planarization layer 180. The anode electrode AE may be connected to the second connection electrode BE2 through a contact hole penetrating the second planarization layer 180. The second sub-power supply line SVSL2 may be connected to the first sub-power supply line SVSL1 through a contact hole penetrating the second planarization layer 180. Further, the second sub-power supply line SVSL2 may be connected to the first sub-power supply line SVSL1 in a dam area DAMA. The power supply line VSL may include a first sub-power supply line SVSL1 and a second sub-power supply line SVSL2. The power supply line VSL may be connected to the light-emitting element ED.

The bank 190 of a bank layer may be disposed on the anode electrode AE. The bank 190 may be a solid material portion in which a bank opening is defined to define a light emitting area EA which corresponds to the bank opening. To this end, the bank 190 may be formed to expose a portion of the anode electrode AE on the second planarization layer 180, to outside the bank layer. The bank 190 may cover an edge of the anode electrode AE.

The light emitting layer EL may be exposed without being covered by the bank 190 and may be disposed on the corresponding anode electrode AE. The light emitting layer EL includes an organic material and may emit a predetermined amount of light. Although not shown, the light emitting layer EL may include a hole transporting layer, an organic material layer, and an electron transporting layer.

The cathode electrode CE may be disposed on the light emitting layer EL and along the bank 190. The cathode electrode CE may be formed to cover the top surface of the light emitting layer EL and the top surface of the bank 190. The cathode electrode CE may be commonly disposed over the entire display area DA (e.g., an entirety of the planar area of the display area DA). In addition, the cathode electrode CE may also be disposed in a portion of the non-display area NDA. For example, the cathode electrode CE may extend from the display area DA to be disposed on the bank 190 and the second sub-power supply line SVSL2 in the non-display area. The cathode electrode CE may be connected to the second sub-power supply line SVSL2.

The first dam DAM1 may include a first sub-dam SDAM1_1 as a first sub-dam layer, a second sub-dam SDAM2_1 as a second sub-dam layer, and a third sub-dam SDAM3_1 as a third sub-dam layer which area sequentially stacked on a power supply line VSL. The first sub-dam SDAM1_1 may be formed of the same material as the second planarization layer 180, the second sub-dam SDAM2_1 may be formed of the same material as the bank 190, and the third sub-dam SDAM3_1 may be formed of the same material as the spacer (e.g., not shown, a spacer as a material pattern disposed on the bank 190 to support the mask).

The second sub-power supply line SVSL2 may be disposed on the first sub-dam SDAM1_1 of the first dam DAM1. The second sub-power supply line SVSL2 may be disposed to cover the first sub-dam SDAM1_1 of the first dam DAM1. For example, the second sub-power supply line SVSL2 may be disposed on the top surface and extend along the side surface of the first sub-dam SDAM1_1 of the first dam DAM1. The second sub-dam SDAM2_1 of the first dam DAM1 may be disposed on the second sub-power supply line SVSL2.

The second dam DAM2 may include a first sub-dam SDAM1_2, a second sub-dam SDAM2_2, a third sub-dam SDAM3_2, and a fourth sub-dam SDAM4_2 sequentially laminated on the second interlayer insulating layer 142. The first sub-dam SDAM1_2 may be formed of the same material as the first planarization layer 160, and the second sub-dam SDAM2_2 may be formed of the same material as the second planarization layer 180. The third sub-dam SDAM3_2 may be formed of the same material as the bank 190, and the fourth sub-dam SDAM4_2 may be formed of the same material as the spacer (e.g., a spacer as a material pattern disposed on the bank 190 to support the mask).

The first sub-dam SDAM1_2 of the second dam DAM2 may be disposed on the second power supply connection electrode VSCE2. Further, the first sub-power supply line SVSL1 may be disposed on the first sub-dam SDAM1_2 of the second dam DAM2, and the second sub-dam SDAM2_2 of the second dam DAM2 may be disposed on the first sub-power supply line SVSL1. In addition, the second sub-power supply line SVSL2 may be disposed on the second sub dam SDAM2_2 of the second dam (DAM2), and the third sub-dam SDAM3_2 of the second dam DAM2 may be disposed on the second sub-power supply line SVSL2.

Outside the second dam DAM2 (e.g., in a direction away from the display area DA), an inorganic encapsulation area IEA including only an inorganic layer may be disposed by portions of the first encapsulation inorganic layer TFE1 and the second encapsulation inorganic layer TFE3 which are outside the second dam DAM2 and contact each other. As used herein, elements which contact each other may form an interface therebetween, such as to form an inorganic encapsulation area IEA. No organic layer is disposed in the inorganic encapsulation area IEA. The display area DA may be surrounded by the inorganic encapsulation area IEA in a plan view, to prevent external oxygen or moisture from penetrating into the light emitting layer EL of the display area DA. The inorganic encapsulation area IEA may be disposed adjacent to an edge of the first side of the display panel 100. The inorganic encapsulation area IEA may be disposed closer to the dam area DAMA than an inorganic area such as where inorganic layers disposed below the encapsulation layer TFE are located.

An encapsulation layer TFE may be formed on the cathode electrode CE, the anode electrode AE, the first dam DAM1, and the second dam DAM2. The encapsulation layer TFE may include at least one inorganic layer to prevent oxygen or moisture from penetrating the light emitting layer EL. Also, the encapsulation layer TFE may include at least one organic layer to prevent a gap from being formed in the at least one inorganic layer due to foreign substances such as dust. In an embodiment, the inorganic layer and the organic layer may extend continuously from the display area DA and into the non-display area NDA.

The encapsulation layer TFE may include a first inorganic encapsulation layer TFE1, an organic encapsulation layer TFE2, and a second inorganic encapsulation layer TFE3 which are sequentially stacked. The first inorganic encapsulation layer TFE1 may be disposed on the cathode electrode CE, the organic encapsulation layer TFE2 may be disposed on the first inorganic encapsulation layer TFE1, and the second inorganic encapsulation layer TFE3 may be disposed on the organic encapsulation layer TFE2.

The first inorganic encapsulation layer TFE1 and the second inorganic encapsulation layer TFE3 may be formed as a multilayer in which one or more inorganic layers of silicon nitride (SiNₓ), silicon oxide nitride (SiON), silicon oxide (SiOₓ), titanium oxide (TiOₓ), or aluminum oxide (AlOₓ) are alternately laminated. The encapsulation organic layer TFE2 may be formed an organic layer such as an acrylic resin, an epoxy resin, a phenolic resin, a polyamide resin, or a polyimide resin.

A sensor layer including a plurality of sensor electrodes SSE for detecting a touch may be disposed on the encapsulation layer TFE. The sensor electrodes SSE may be disposed on the encapsulation layer TFE so as not to overlap with the light emitting area EA. For example, the sensor electrodes SSE may be disposed on the encapsulation layer TFE to overlap with the bank 190 of the bank layer. The sensor electrodes SSE may be made of a material including a metal. For example, the sensor electrode SSE may be made of a material including molybdenum (Mo). Within the sensor layer, an insulating layer 210 may be arranged on the sensor electrodes SSE.

In addition, an auxiliary layer AXL may be further disposed on the encapsulation layer TFE. The auxiliary layer AXL as an auxiliary pattern may be disposed, for example, between the display area DA of the substrate SUB and the outer edge of the substrate SUB. For example, the auxiliary layer AXL may be disposed between the display area DA and the dam area DAMA. At this time, in a planar view, the pattern of the auxiliary layer AXL may have a shape of a closed curve surrounding the display area DA. That is, the auxiliary pattern may have a discrete shape. The auxiliary layer AXL may be made of the same material as the sensor electrode SSE described above. For example, the auxiliary layer AXL may be made of a material including a metal. The thickness of the auxiliary layer AXL may be greater than the thickness of the sensor electrode SSE. Here, the thickness may be in the direction from the substrate SUB to the cover window CSUB. For example, the thickness may be a size or dimension in the third direction DR3, such as a direction normal to the plane defined by the first direction DR1 and the second direction DR2 crossing each other. The auxiliary layer AXL may have a rectangular or rectilinear cross-section.

A polarizing layer POL may be disposed on the encapsulation layer TFE and the insulating layer 210 to prevent visibility degradation due to external light. The polarizing layer POL may include a first base member, a linear polarizing plate, a phase retardation film such as a quarter-wave plate (a λ/4 plate), and a second base member. The polarizing layer POL may be replaced with another anti-reflection layer such as a color filter layer including a plurality of color filters.

A light control layer LCF may be disposed on the polarizing layer POL. The light control layer LCF may improve the straightness of light. In an embodiment, the light control layer LCF may be omitted.

An adhesive layer ADL may be disposed on the encapsulation layer TFE, the polarizing layer POL, and the light control layer LCF. The adhesive layer ADL may be a transparent adhesive layer ADL. The adhesive layer ADL may include a transparent adhesive resin (OCR, optically clear resin).

A cover window CSUB may be disposed on the adhesive layer ADL. A light blocking layer BM may be disposed on one surface of the cover window CSUB. The cover window CSUB and the aforementioned polarizing layer POL (or the polarizing layer POL and the light control layer LCF) may be adhered to each other by the adhesive layer ADL.

The adhesive layer ADL may be disposed on the display area DA to overlap the entire surface of the display area DA in a planar view. At this time, an edge of the adhesive layer ADL may be disposed in a non-display area NDA. The edge may be an end surface which is furthest from the display area DA. For example, the edge of the adhesive layer ADL may be disposed between, for example, the display area DA and the dam area DAMA. At this time, the edge of the adhesive layer ADL may be in contact with the auxiliary layer AXL. For example, an edge of the adhesive layer ADL may be disposed on the auxiliary layer AXL. Specifically, the edge of the adhesive layer ADL may be disposed between the auxiliary layer AXL and the cover window CSUB. In other words, the edge of the adhesive layer ADL may be disposed between the auxiliary layer AXL and the light blocking layer BM. In an embodiment, the edge of the adhesive layer ADL may be furthest from the display area and overlapping the auxiliary pattern, and the adhesive layer ADL extends continuously from the edge thereof to the encapsulation layer TFE in the display area DA.

The adhesive layer ADL may be formed of a material including a resin. The resin may be a liquid resin having viscosity. The resin may be a resin having light transmittance, and in some embodiments, the resin may be a photocurable resin or a thermosetting resin.

The adhesive layer ADL may include a first adhesive layer ADL1 and a second adhesive layer ADL2. The first adhesive layer ADL1 and the second adhesive layer ADL2 may be formed integrally. Here, even though a solid line is shown between the first adhesive layer ADL1 and the second adhesive layer ADL2 in FIG. 3, it will be understood that such line may indicate a virtual boundary between the two layers, and the first adhesive layer ADL1 and the second adhesive layer ADL2 may be continuous with each other such as to form a single body. The first adhesive layer ADL1 and the second adhesive layer ADL2 may each include a transparent adhesive resin.

The first adhesive layer ADL1 as a first adhesive pattern may be disposed in the non-display area NDA. For example, the first adhesive layer ADL1 may be disposed on the outside of the display area DA to surround the display area DA in a planar view. Specifically, the first adhesive layer ADL1 may be disposed between the display area DA and the dam area DAMA. The first adhesive layer ADL1 may be disposed between the encapsulation layer TFE and the cover window CSUB. At this time, the first adhesive layer ADL1 may be disposed on the auxiliary layer AXL. For example, the first adhesive layer ADL1 may be disposed between the auxiliary layer AXL and the cover window CSUB. Specifically, the first adhesive layer ADL1 may be disposed between the auxiliary layer AXL and the light blocking layer BM. The top surface of the first adhesive layer ADL1 which is closest to or faces the light blocking layer BM may have a round cross-section. Here, the top surface may include an apex such as to define a distal end of the shape of the first adhesive layer ADL1. The contact area between the first adhesive layer ADL1 and the overlying layer (e.g., the light blocking layer BM may be minimal owing to the shape of the top surface of the first adhesive layer ADL1. However, embodiments are not limited thereto such that an upper surface of the adhesive layer ADL which faces the cover window CSUB may be curved in cross-section or be straight in cross-section.

The second adhesive layer ADL2 as a second adhesive pattern may be disposed on the display area DA and the non-display area NDA. The second adhesive layer ADL2 may be disposed on the encapsulation layer TFE, the polarization layer POL and the light control layer LCF to overlap the entire surface of the display area DA. The second adhesive layer ADL2 may be surrounded by the first adhesive layer ADL1 in a planar view. The second adhesive layer ADL2 may be disposed between the encapsulation layer TFE and the cover window CSUB. Overflow of a material for forming the second adhesive layer ADL2 may be prevented by the auxiliary layer AXL described above. For example, the raw material (e.g., resin in a flowable form, like a liquid) of the second adhesive layer ADL2 may be discharged onto the substrate SUB by an inkjet printing method, and at this time, the spreading and overflow of the raw material of the second adhesive layer ADL2 in a direction away from the display area DA may be restricted or prevented by the auxiliary layer AXL described above.

On the other hand, the first adhesive layer ADL1 and the second adhesive layer ADL2 may be manufactured (or formed) by separate processes. For example, the first adhesive layer ADL1 may be formed first, and then the second adhesive layer ADL2 may be formed. After respective material for forming the first adhesive layer ADL1 and the second adhesive layer ADL2 are cured, an interface between the first adhesive layer ADL1 and the second adhesive layer ADL2 may not exist (e.g., a virtual boundary therebetween). For example, the first adhesive layer ADL1 and the second adhesive layer ADL2 may be formed integrally without an interface after each curing.

In an embodiment, a display device 10 includes a substrate SUB including a display area DA and a non-display area NDA adjacent to each other, a transistor layer TFTL in the display area DA, a light emitting element layer (e.g., layers inclusive of layers in the light emitting element ED) in the display area DA and electrically connected to the transistor layer TFTL an encapsulation layer TFE on the light emitting element layer and in the non-display area NDA, an auxiliary pattern (e.g., AXL) which is on the encapsulation layer TFE in the non-display area, and spaced apart from the display area DA, and an adhesive layer SDL on the encapsulation layer TFE and the auxiliary pattern.

The display device 10 may further include a sensor electrode SSE on the encapsulation layer TFE, in the display area DA and the auxiliary pattern may be in a same layer as the sensor electrode SSE. Here, the sensor electrode SSE may include conductive layers stacked along a thickness direction of the substrate SUB (e.g., along the third direction DR3), and the auxiliary pattern may include sub-auxiliary layers stacked along the thickness direction of the substrate SUB. The number of the conductive layers within the sensor electrode SSE and the number of the sub-auxiliary layers within the auxiliary pattern may be the same as each other. The sub-auxiliary layers within the auxiliary pattern may be in same layers as the conductive layers within the sensor electrode SSE, respectively.

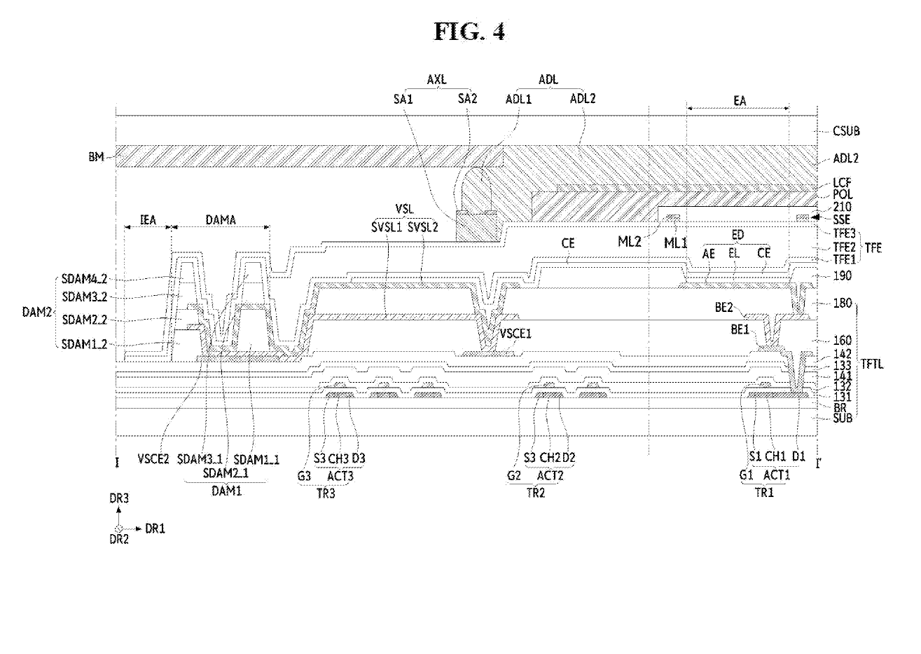

FIG. 4 is a cross-sectional view of a display device 10 according to an embodiment of the present invention along the line I-I’ of FIG. 2.

The display device 10 of FIG. 4 has differences from the display device 10 of FIG. 3 described above in terms of the sensor electrode SSE and the auxiliary layer AXL, and the differences will be mainly described as follows.

As shown in FIG. 4, the sensor electrode SSE may include a first conductive layer ML1 and a second conductive layer ML2 disposed along the thickness direction (e.g., the third direction DR3) of the sensor electrode SSE.

The first conductive layer ML1 may be disposed on the encapsulation layer TFE. The first conductive layer ML1 may be made of a material including a metal. For example, the first conductive layer ML1 may include molybdenum.

The second conductive layer ML2 may be disposed on the first conductive layer ML1. The second conductive layer ML2 may be in contact (or direct contact) with the first conductive layer ML1. The second conductive layer ML2 may be made of a material including a metal. The second conductive layer ML2 may include a different material from the first conductive layer ML1. For example, the second conductive layer ML2 may include nickel (Ni).

The auxiliary layer AXL may include a first sub-auxiliary layer SA1 and a second sub-auxiliary layer SA2 disposed along a thickness direction of the auxiliary layer AXL (e.g., third direction DR3). For example, the number of sub-auxiliary layers of the auxiliary layer AXL may be the same as the number of conductive layers of the sensor electrode SSE. At this time, the respective sub-auxiliary layer and the conductive layer disposed on the same layer may include the same material. For example, the first sub-auxiliary layer SA1 and the first conductive layer ML1 disposed on the same layer may be made of the same material, and the second sub-auxiliary layer SA2 and the second conductive layer ML2 disposed on the same layer may be made of the same material.

Since the first sub-auxiliary layer SA1 is the same as the auxiliary layer AXL of FIG. 3 described above, the description of the first sub-auxiliary layer SA1 refers to the auxiliary layer AXL of FIG. 3 and the related description. The first sub-auxiliary layer SA1 may be made of the same material as the first conductive layer ML1. For example, the first sub-auxiliary layer SA1 may be made of a material including molybdenum.

The second sub-auxiliary layer SA2 may be disposed on the first sub-auxiliary layer SA1. For example, the second sub-auxiliary layer SA2 may include patterns disposed at opposing edges of the first sub-auxiliary layer SA1 in a direction from the display area DA to the non-display area NDA. The auxiliary layer AXL may have a recess (or groove) defined open in an upward direction, and a volume portion of the first adhesive layer ADL1 may occupy the volume of the recess. In a planar view, the second sub-auxiliary layer SA2 may extend along the first sub-auxiliary layer SA1. For example, in a planar view, the second sub-auxiliary layer SA2 may be disposed extended along both of the opposing edges of the first sub-auxiliary layer SA1. In a planar view, the second sub-auxiliary layer SA2 may have a closed curve shape surrounding the second adhesive layer ADL2. The first sub-auxiliary layer SA1 may be exposed to outside the second sub-auxiliary layer SA2. The second sub-auxiliary layer SA2 may be in contact (or in direct contact) with the first sub-auxiliary layer SA1. The second sub-auxiliary layer SA2 may have a rectangular cross-section. The second sub-auxiliary layer SA2 may be made of the same material as the second conductive layer ML2. For example, the second sub-auxiliary layer SA2 may be made of a material including nickel.

The first adhesive layer ADL1 may be disposed on the first sub-auxiliary layer SA1 and the second sub-auxiliary layer SA2. At this time, a portion of the first adhesive layer ADL1 may be disposed between the second sub-auxiliary layers SA2 and such portion may contact an exposed portion of the first sub-auxiliary layer SA1.

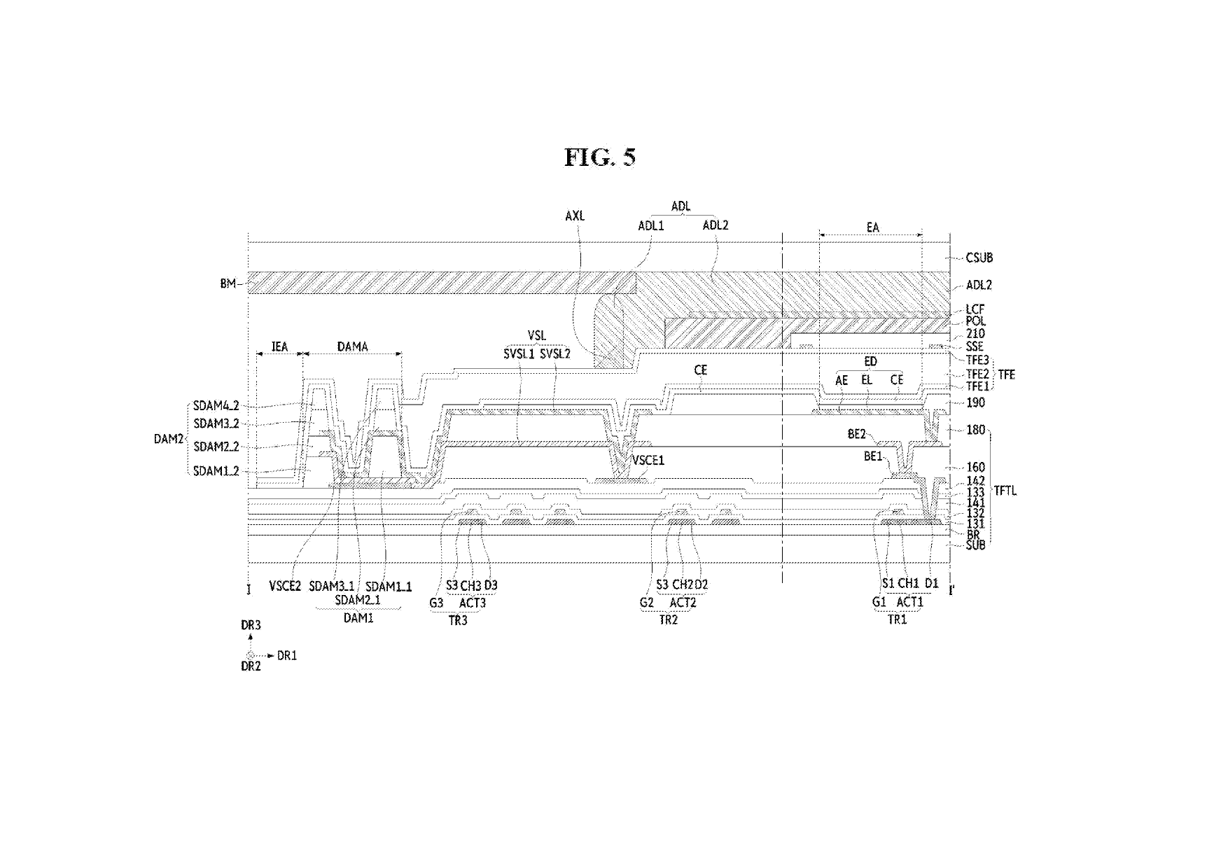

FIG. 5 is a cross-sectional view of a display device 10 according to an embodiment of the present invention along the line I-I’ of FIG. 2.

The display device 10 of FIG. 5 has a difference from the display device 10 of FIG. 3 described above in the shape of the auxiliary layer AXL, and this difference will be mainly described as follows.

As shown in FIG. 5, the auxiliary layer AXL may have a triangular cross-section. The second adhesive layer ADL2 may be disposed on the hypotenuse or inclined upper surface of the auxiliary layer AXL. Here, a height of the auxiliary layer AXL is greatest at a location closest to the display area DA while the height decreases in a direction from the display area DA to the non-display area NDA. However, the embodiments are not limited thereto such that the auxiliary pattern (e.g., the auxiliary layer AXL) may have a cross-section of a square shape or a cross-section of a triangular shape.

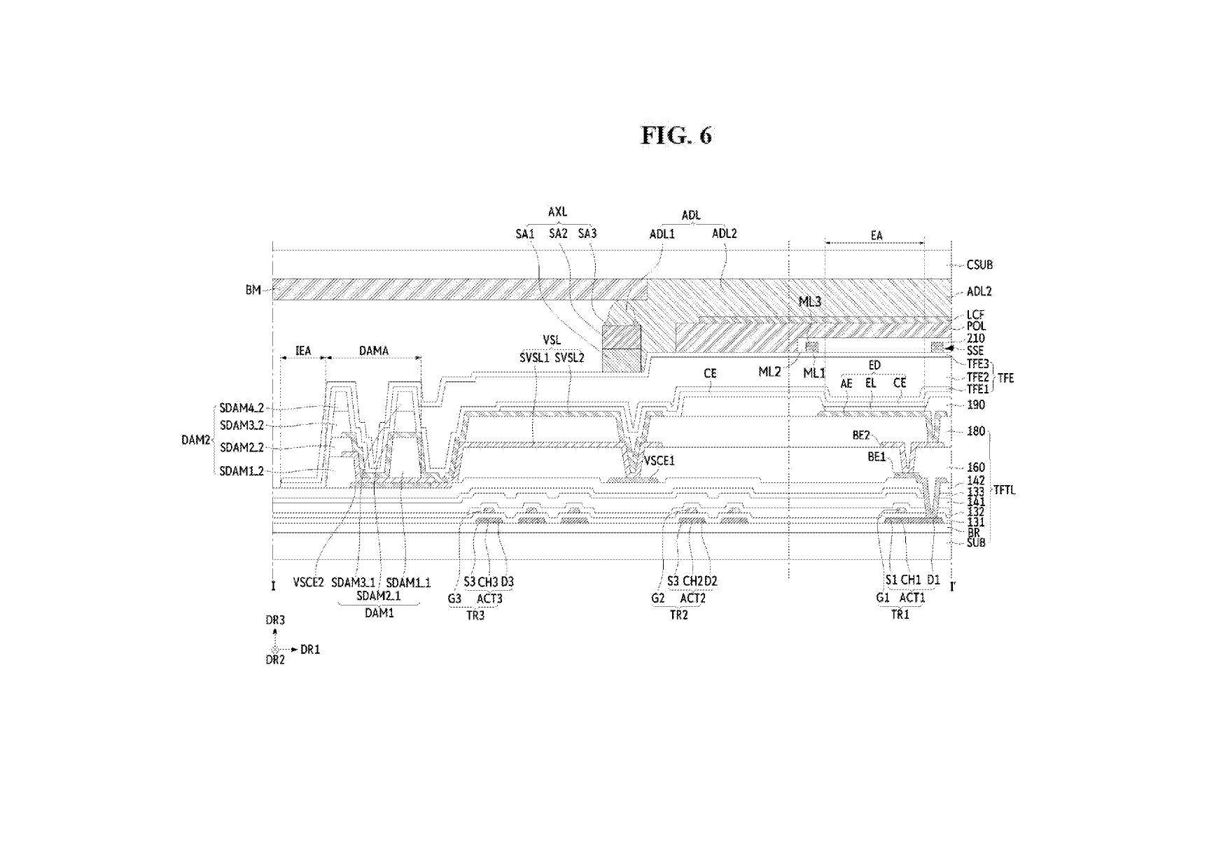

FIG. 6 is a cross-sectional view of a display device 10 according to an embodiment of the present invention along the line I-I’ of FIG. 2.

The display device 10 of FIG. 6 has differences from the display device of FIG. 3 described above in terms of the sensor electrode SSE and the auxiliary layer AXL, and the differences will be mainly described as follows.

As shown in FIG. 6, the sensor electrode SSE may include a first conductive layer ML1, a second conductive layer ML2, and a third conductive layer ML3 disposed along the thickness direction (e.g., the third direction DR3) of the sensor electrode SSE.

The first conductive layer ML1 may be disposed on the encapsulation layer TFE. The first conductive layer ML1 may be made of a material including a metal. For example, the first conductive layer ML1 may include molybdenum.

The second conductive layer ML2 may be disposed on the first conductive layer ML1. For example, the second conductive layer ML2 may be disposed between the first conductive layer ML1 and the third conductive layer ML3. The second conductive layer ML2 may be in contact (or in direct contact) with each of the first conductive layer ML1 and the third conductive layer ML3. The second conductive layer ML2 may include a different material from the first conductive layer ML1. For example, the second conductive layer ML2 may include nickel.

The third conductive layer ML3 may be disposed on the second conductive layer ML2. The third conductive layer ML3 may be in contact (or in direct contact) with the second conductive layer ML2. The third conductive layer ML3 may include a different material from the first conductive layer ML1 and the second conductive layer ML2. For example, the third conductive layer ML3 may be made of a material including aluminum (Al).

The auxiliary layer AXL may include a first sub-auxiliary layer SA1, a second sub-auxiliary layer SA2, and a third sub-auxiliary layer SA3 disposed in order along the thickness direction of the auxiliary layer AXL (e.g., the third direction DR3). For example, the number of sub-auxiliary layers of the auxiliary layer AXL may be the same as the number of conductive layers of the sensor electrode SSE. At this time, the sub-auxiliary layer and the conductive layer disposed on the same layer may include the same material. For example, the first sub-auxiliary layer SA1 and the first conductive layer ML1 arranged on the same layer may be made of the same material, the second sub-auxiliary layer SA2 and the second conductive layer ML2 disposed on the same layer may be made of the same material, and the third sub-auxiliary layer SA3 and the third conductive layer ML3 disposed on the same layer may be made of the same material.

Since the first sub-auxiliary layer SA1 is the same as the auxiliary layer AXL of FIG. 3 described above, the description of the first sub-auxiliary layer SA1 refers to the auxiliary layer AXL of FIG. 3 and the related description. The first sub-auxiliary layer SA1 may be made of the same material as the first conductive layer ML1. For example, the first sub-auxiliary layer SA1 may be made of a material including molybdenum.

The second sub-auxiliary layer SA2 may be disposed on the first sub-auxiliary layer SA1. In a planar view, the second sub-auxiliary layer SA2 may be disposed extended along the first sub-auxiliary layer SA1. In a planar view, the second sub-auxiliary layer SA2 may have a closed curve shape surrounding the first adhesive layer ADL1. The second sub-auxiliary layer SA2 may be in contact (or direct contact) with the first sub-auxiliary layer SA1 and the third sub-auxiliary layer SA3, respectively. The second sub-auxiliary layer SA2 may have a rectangular cross-section. The second sub-auxiliary layer SA2 may be made of the same material as the second conductive layer ML2. For example, the second sub-auxiliary layer SA2 may be made of a material including nickel.

The third sub-auxiliary layer SA3 may be disposed on the second sub-auxiliary layer SA2. For example, the third sub-auxiliary layer SA3 may be disposed at both edges of the second sub-auxiliary layer SA2. In a planar view, the third sub-auxiliary layer SA3 may be disposed extended along the second sub-auxiliary layer SA2. For example, in a planar view, the third sub-auxiliary layer SA3 may be disposed extended along both edges of the second sub-auxiliary layer SA2. In a planar view, the third sub-auxiliary layer SA3 may have a closed curve shape surrounding the second adhesive layer ADL2. The third sub-auxiliary layer SA3 may be in contact (or in direct contact) with the second sub-auxiliary layer SA2. The third sub-auxiliary layer SA3 may have a triangular cross-section. The third sub-auxiliary layer SA3 may be made of the same material as the third conductive layer ML3. For example, the third sub-auxiliary layer SA3 may be made of a material including aluminum.

The first adhesive layer ADL1 may be disposed on the second sub-auxiliary layer SA2 and the third sub-auxiliary layer SA3. At this time, a portion of the first adhesive layer ADL1 may be disposed between the third sub-auxiliary layers SA3 and such portion may contact an exposed portion of the second sub-auxiliary layer SA2.

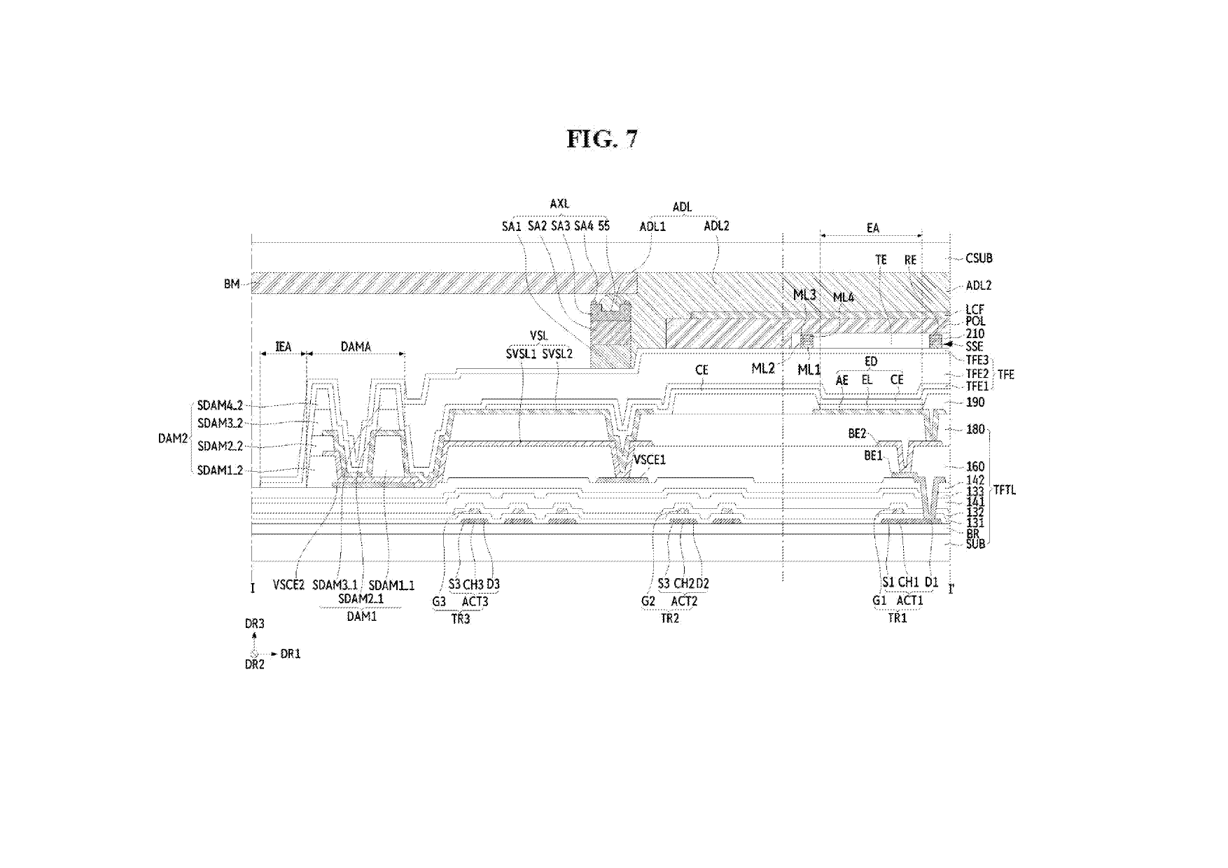

FIG. 7 is a cross-sectional view of a display device 10 according to an embodiment of the present invention along the line I-I’ of FIG. 2.

The display device 10 of FIG. 7 has differences from the display device 10 of FIG. 3 described above in terms of the sensor electrode SSE and the auxiliary layer AXL, and the differences will be mainly described as follows.

As shown in FIG. 7, the sensor electrode SSE may include a first conductive layer ML1, a second conductive layer ML2, a third conductive layer ML3 and a fourth conductive layer ML4 disposed in order along the thickness direction (e.g., the third direction DR3) of the sensor electrode SSE.

The first conductive layer ML1 may be disposed on the encapsulation layer TFE. The first conductive layer ML1 may be made of a material including a metal. For example, the first conductive layer ML1 may include molybdenum.

The second conductive layer ML2 may be disposed on the first conductive layer ML1. For example, the second conductive layer ML2 may be disposed between the first conductive layer ML1 and the third conductive layer ML3. The second conductive layer ML2 may be in contact (or in direct contact) with each of the first conductive layer ML1 and the third conductive layer ML3. The second conductive layer ML2 may include a different material from the first conductive layer ML1. For example, the second conductive layer ML2 may include nickel.

The third conductive layer ML3 may be disposed on the second conductive layer ML2. For example, the third conductive layer ML3 may be disposed between the second conductive layer ML2 and the fourth conductive layer ML4. The third conductive layer ML3 may be in contact (or direct contact) with the second conductive layer ML2 and the fourth conductive layer ML4, respectively. The third conductive layer ML3 may include a material different from the first conductive layer ML1 and the second conductive layer ML2. For example, the third conductive layer ML3 may be made of a material including aluminum.

The fourth conductive layer ML4 may be disposed on the third conductive layer ML3. The fourth conductive layer ML4 may be in contact (or direct contact) with the third conductive layer ML3. The fourth conductive layer ML4 may include a material different from the first conductive layer ML1, the second conductive layer ML2, and the third conductive layer ML3. For example, the fourth conductive layer ML4 may be made of a material including ITO (Indium-Tin-Oxide).

The auxiliary layer AXL may include a first sub-auxiliary layer SA1, a second sub-auxiliary layer SA2, a third sub-auxiliary layer SA3, and a fourth sub-auxiliary layer SA4 disposed in order along the thickness direction of the auxiliary layer AXL (e.g., the third direction DR3). For example, the number of sub-auxiliary layers of the auxiliary layer AXL may be the same as the number of conductive layers of the sensor electrode SSE. In this case, the sub-auxiliary layer and the conductive layer disposed on the same layer may include the same material. For example, the first sub-auxiliary layer SA1 and the first conductive layer ML1 disposed on the same layer may be made of the same material, the second sub-auxiliary layer SA2 and the second conductive layer ML2 disposed on the same layer may be made of the same material, the third sub-auxiliary layer SA3 and the third conductive layer ML3 disposed on the same layer may be made of the same material, and the fourth sub-auxiliary layer SA4 and the fourth conductive layer ML4 disposed on the same layer may be made of the same material.

Since the first sub-auxiliary layer SA1 is the same as the auxiliary layer AXL of FIG. 3 described above, the description of the first sub-auxiliary layer SA1 refers to the auxiliary layer AXL of FIG. 3 and the related description. The first sub-auxiliary layer SA1 may be made of the same material as the first conductive layer ML1. For example, the first sub-auxiliary layer SA1 may be made of a material including molybdenum.

The second sub-auxiliary layer SA2 may be disposed on top of the first sub- auxiliary layer SA1. In a plan view, the second sub-auxiliary layer SA2 may be disposed extended along the first sub-auxiliary layer SA1. In a plan view, the second sub-auxiliary layer SA2 may have a closed curve shape surrounding the first adhesive layer ADL1. The second sub-auxiliary layer SA2 may contact (or directly contact) the first sub-auxiliary layer SA1 and the third sub-auxiliary layer SA3, respectively. The second sub-auxiliary layer SA2 may have a rectangular cross-section. The second sub-auxiliary layer SA2 may be made of the same material as the second conductive layer ML2. For example, the second sub-auxiliary layer SA2 may be made of a material including nickel.

The third sub-auxiliary layer SA3 may be disposed on the second sub-auxiliary layer SA2. In a plan view, the third sub-auxiliary layer SA3 may be disposed extended along the second sub-auxiliary layer SA2. In a plan view, the third sub-auxiliary layer SA3 may have a shape of a closed curve surrounding the first adhesive layer ADL1. The third sub-auxiliary layer SA3 may have a groove 55 defined therein. The groove 55 may have a shape which is sunken or concave along a direction toward the second sub-auxiliary layer SA2 (e.g., the reverse direction of the third direction DR3 (hereinafter, the third reverse direction)). In a plan view, the groove 55 may have a shape of a closed curve surrounding the second adhesive layer ADL2. The third sub-auxiliary layer SA3 may be in contact (or direct contact) with the second sub-auxiliary layer SA2 and the fourth sub-auxiliary layer SA4, respectively. The third sub-auxiliary layer SA3 may be made of the same material as the third conductive layer ML3. For example, the third sub-auxiliary layer SA3 may be made of a material including aluminum.

The fourth sub-auxiliary layer SA4 may be disposed on the third sub-auxiliary layer SA3. For example, the fourth sub-auxiliary layer SA4 may be disposed at both edges of the third sub-auxiliary layer SA3. In a plan view, the fourth sub-auxiliary layer SA4 may be disposed extended along the third sub-auxiliary layer SA3. For example, in a plan view, the fourth sub-auxiliary layer SA4 may be disposed extended along both edges of the third sub-auxiliary layer SA3. In a plan view, the fourth sub-auxiliary layer SA4 may have a closed curve shape surrounding the second adhesive layer ADL2. The fourth sub-auxiliary layer SA4 may be in contact (or direct contact) with the third sub-auxiliary layer SA3. The fourth sub-auxiliary layer SA4 may have a semicircular cross-section. The fourth sub-auxiliary layer SA4 may be made of the same material as the fourth conductive layer ML4. For example, the fourth sub-auxiliary layer SA4 may be made of a material including ITO.

The first adhesive layer ADL1 may be disposed on the third sub-auxiliary layer SA3 and the fourth sub-auxiliary layer SA4. In this case, a portion of the first adhesive layer ADL1 may be disposed between the fourth sub-auxiliary layers SA4 and such portion may contact an exposed portion of the third sub-auxiliary layer SA3. For example, a portion of the first adhesive layer ADL1 may be disposed within the groove of the third sub-auxiliary layer SA3 between the fourth sub-auxiliary layers SA4.

In an embodiment, the sub-auxiliary layers within the auxiliary layer AXL may include a first sub-auxiliary layer in a same layer as the first conductive layer of the sensor electrode SSE, a second sub-auxiliary layer in a same layer as the second conductive layer of the sensor electrode SSE, a third sub-auxiliary layer in a same layer as the third conductive layer of the sensor electrode SSE and having a first side closest to the display area DA and a second side which is opposite to the first side, and a fourth sub-auxiliary layer which is in a same layer as the fourth conductive layer. Here, the fourth sub-auxiliary layer may include patterns which are respectively at the first side and the second side of the third sub-auxiliary layer and spaced apart from each other along the third sub-auxiliary layer by a gap.

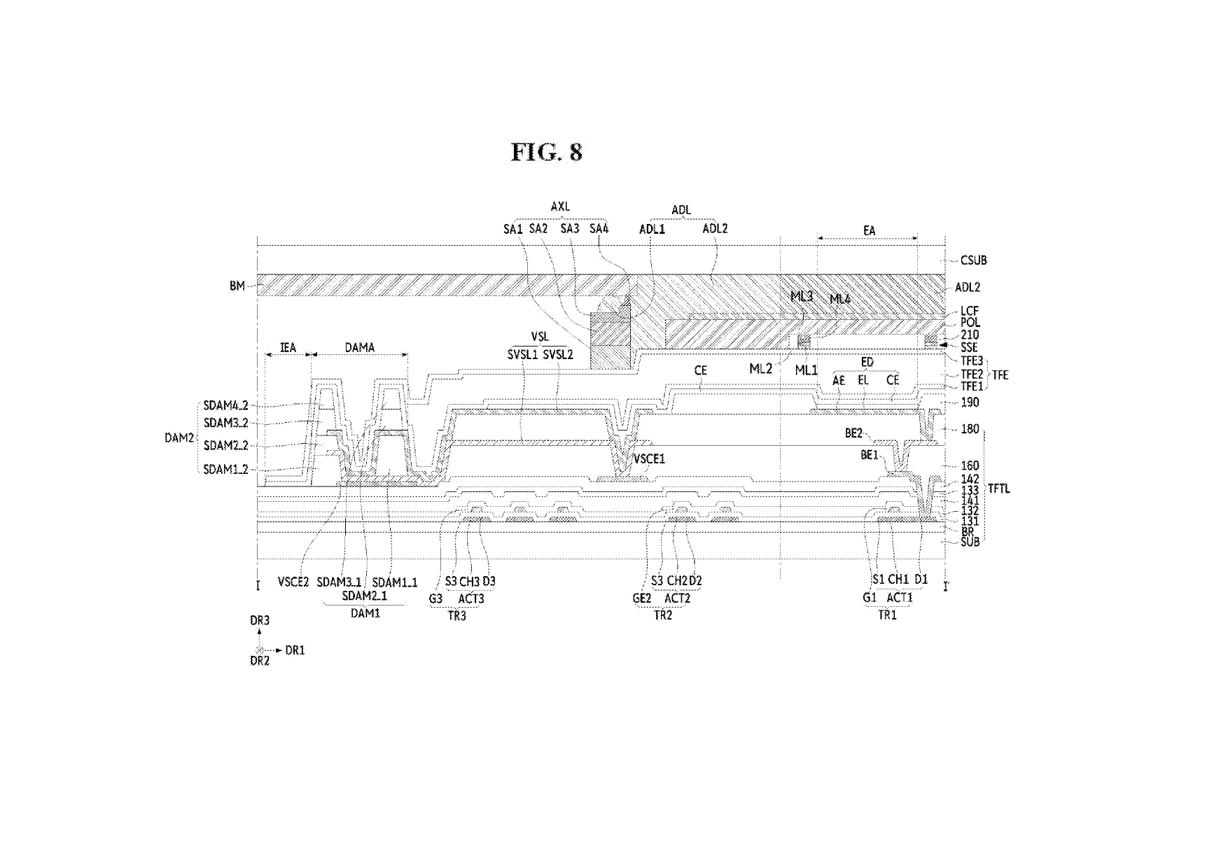

FIG. 8 is a cross-sectional view of a display device 10 according to an embodiment of the present invention along the line I-I’ of FIG. 2.

The display device 10 of FIG. 8 has differences from the display device 10 of FIG. 7 described above in the shapes of the third sub-auxiliary layer SA3 and the fourth sub-auxiliary layer SA4, and the differences will be mainly described as follows.

As shown in FIG. 8, the third sub-auxiliary layer SA3 may have an L-shaped cross-section instead of a grooved-shape. For example, the third sub-auxiliary layer SA3 may have a thicker thickness in an area adjacent to the second adhesive layer ADL2. Here, the thickness may be a size in the third direction DR3. A maximum height of the third sub-auxiliary layer SA3 may be at a side thereof which is closest to the display area DA.

As shown in FIG. 8, the fourth sub-auxiliary layer SA4 may be disposed on one edge of the third sub-auxiliary layer SA3, such as at an edge of the third sub-auxiliary layer SA3 which is closest to the display area DA. For example, the fourth sub-auxiliary layer SA4 may be disposed on one edge of the third sub-auxiliary layer SA3 to overlap with a thicker portion of the third sub-auxiliary layer SA3. The stepped shape of the third auxiliary layer SA3 may be defined by the L-shape of the third auxiliary layer SA3 together with the fourth sub-auxiliary layer SA4, and such stepped shape may be open in a direction away from the display area DA to have a minimum thickness at a side of the third sub-auxiliary layer SA3 which is furthest from the display area DA.

In an embodiment, the fourth sub-auxiliary layer may be disposed spaced apart from the second side of the third sub-auxiliary layer and may be excluded from the second side of the third sub-auxiliary layer.

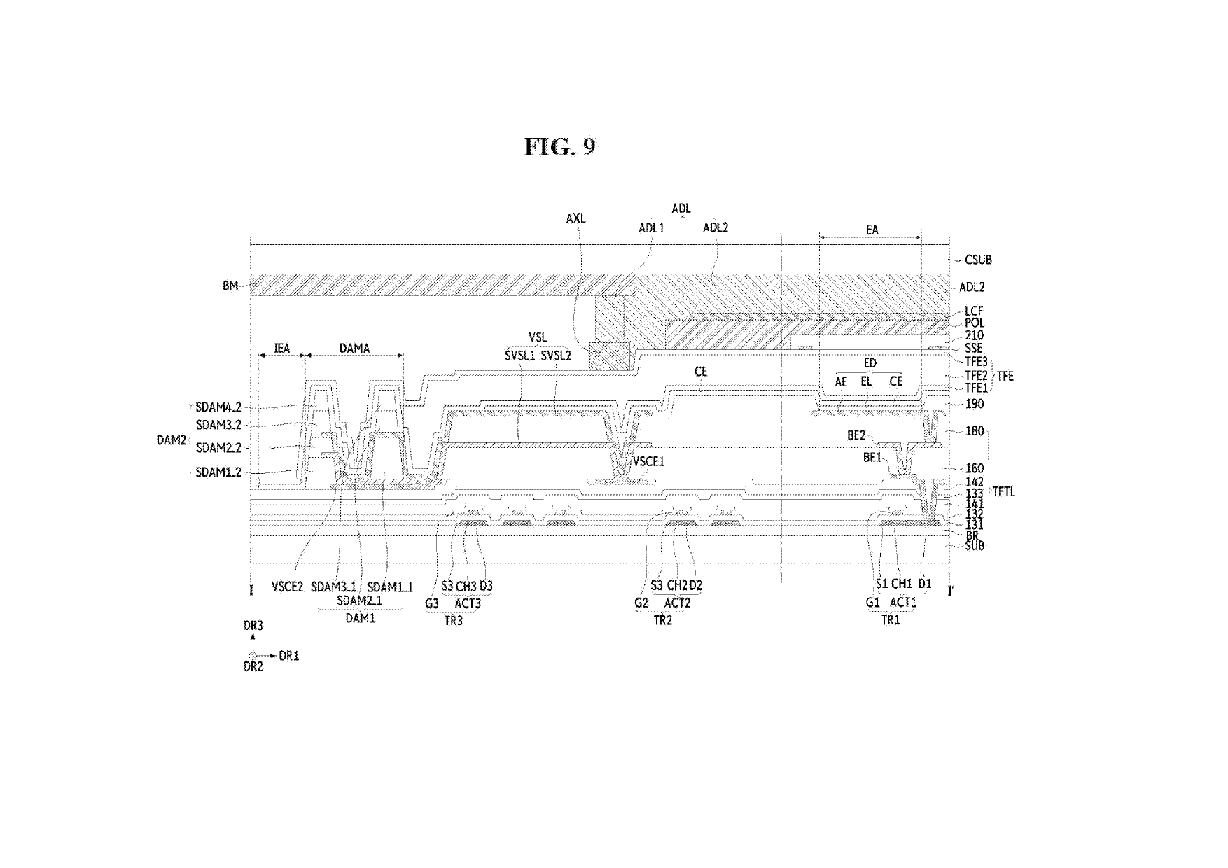

FIG. 9 is a cross-sectional view of a display device 10 according to an embodiment of the present invention along the line I-I’ of FIG. 2.

The display device 10 of FIG. 9 has a difference from the display device 10 of FIG. 3 described above in the shape of the first adhesive layer ADL1, and this difference will be mainly explained as follows.

As shown in FIG. 9, the first adhesive layer ADL1 may have a rectangular cross-section. The contact area between the first adhesive layer ADL1 and the overlying layer (e.g., the light blocking layer BM may be maximum owing to the shape of the top surface of the first adhesive layer ADL1.

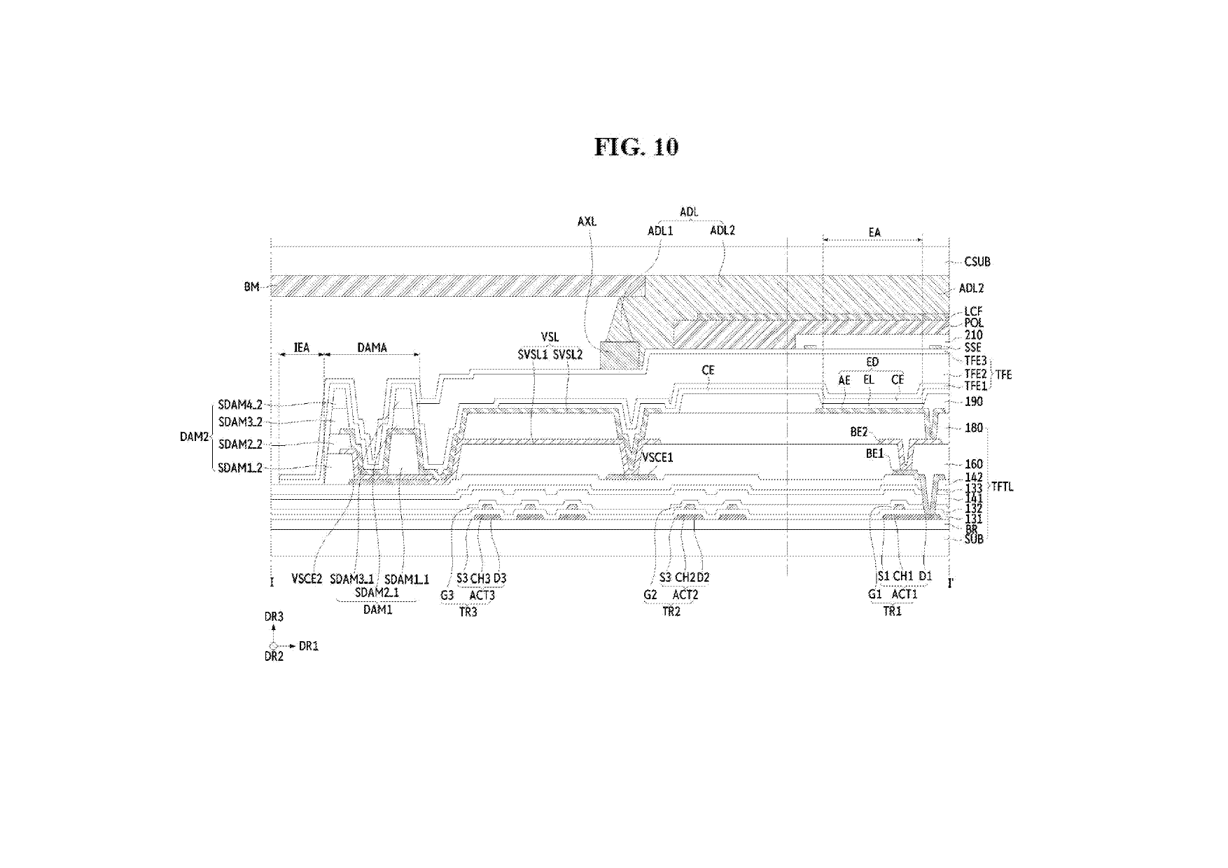

FIG. 10 is a cross-sectional view of a display device 10 according to an embodiment of the present invention along the line I-I’ of FIG. 2.

The display device 10 of FIG. 10 has a difference from the display device 10 of FIG. 3 described above in the shape of the first adhesive layer ADL1, and this difference will be mainly described as follows.

As shown in FIG. 10, the first adhesive layer ADL1 may have a cross-section having a triangular shape. For example, the edge of the adhesive layer ADL including the first adhesive layer ADL1 and the second adhesive layer ADL2 may have a sloped surface. Each of an inner sloped surface and an outer sloped surface among the sloped surfaces may extend from a top surface (e.g., apex) to a base of the first adhesive layer ADL1.

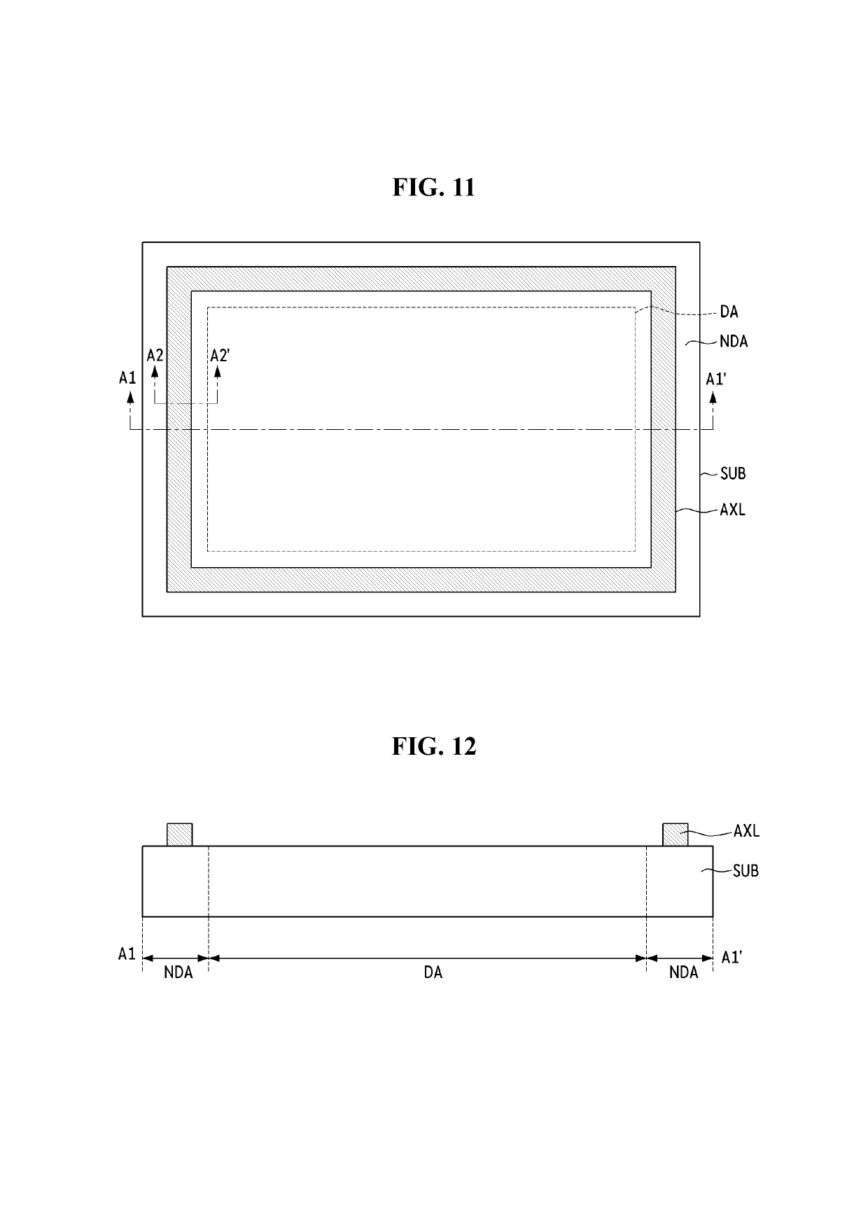

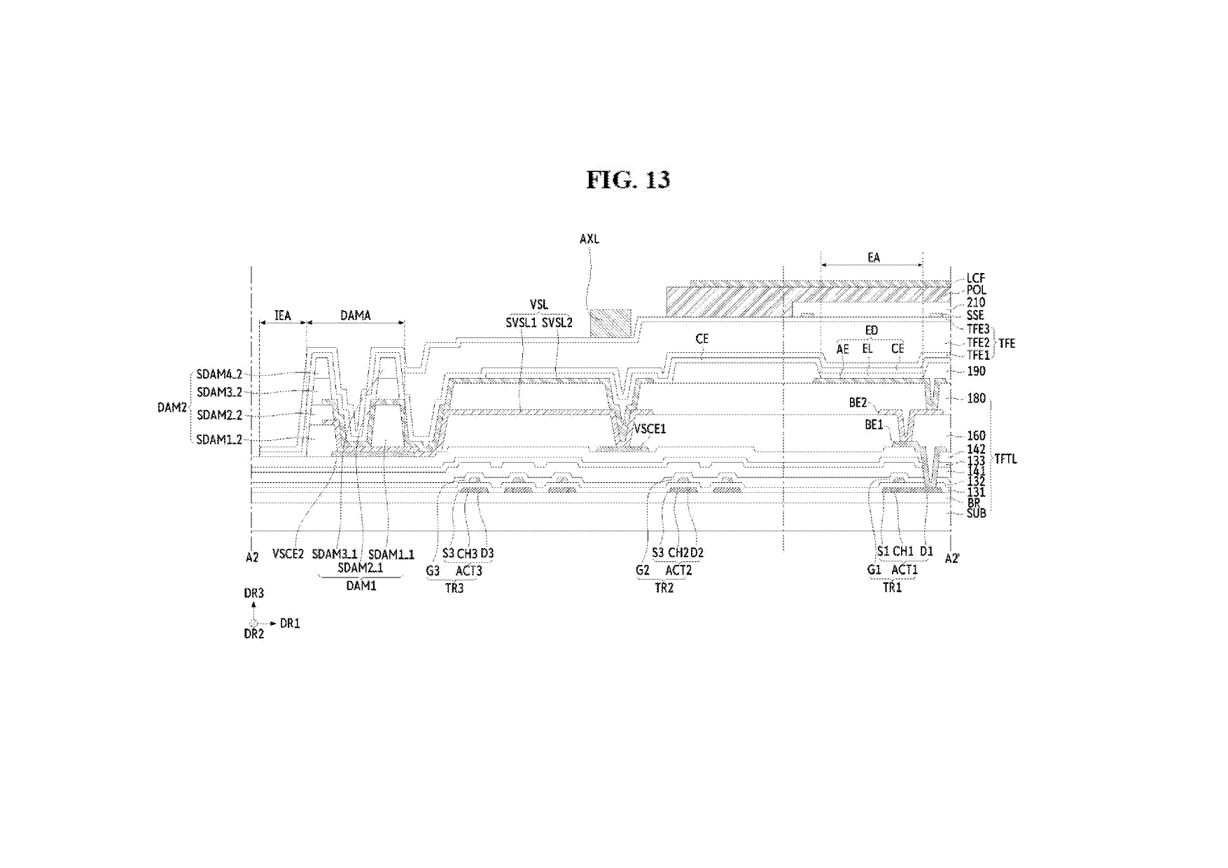

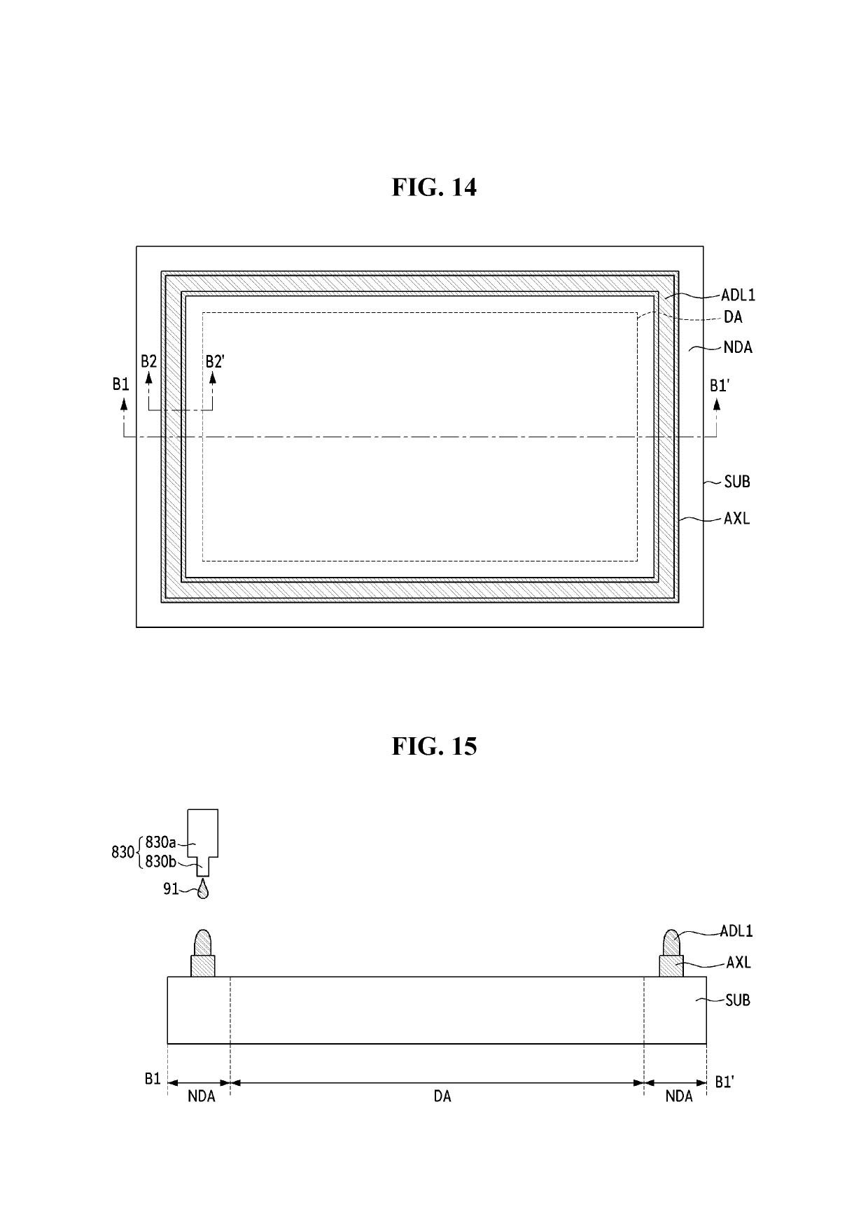

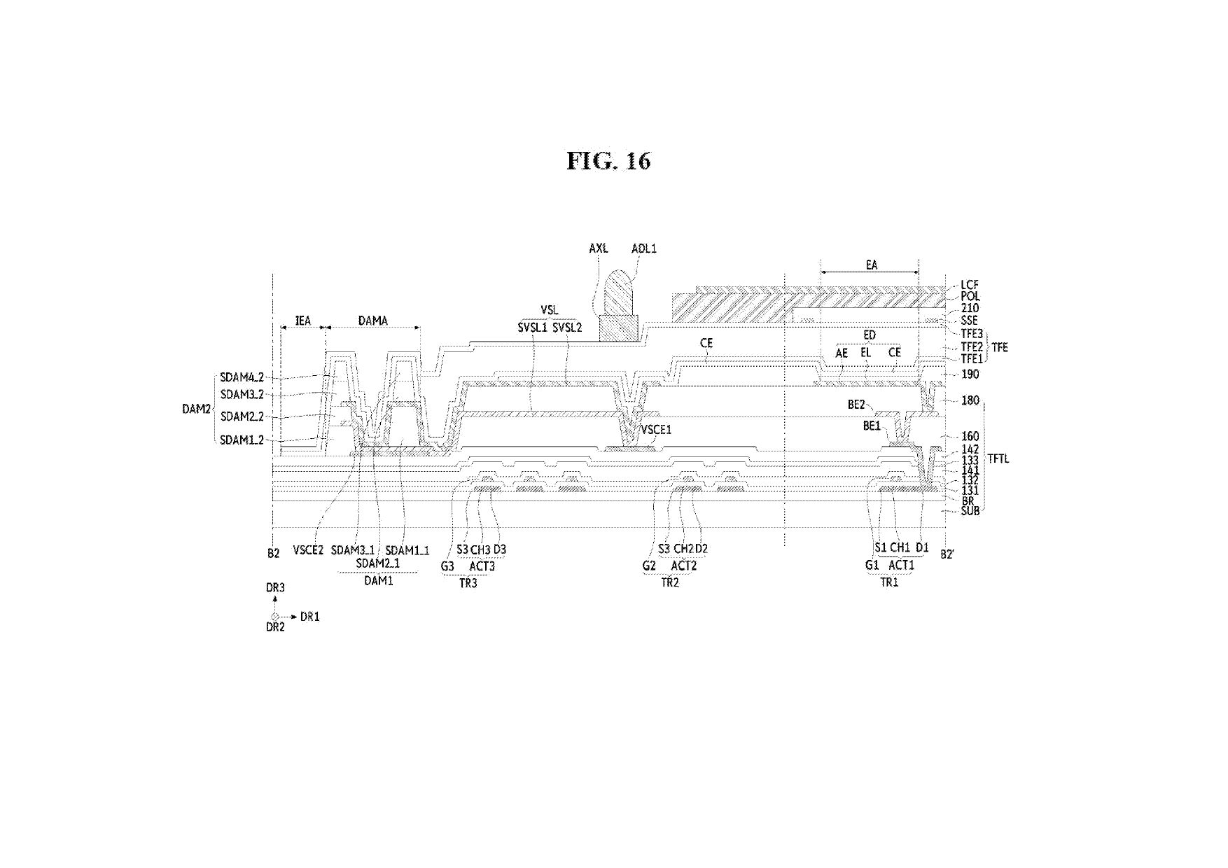

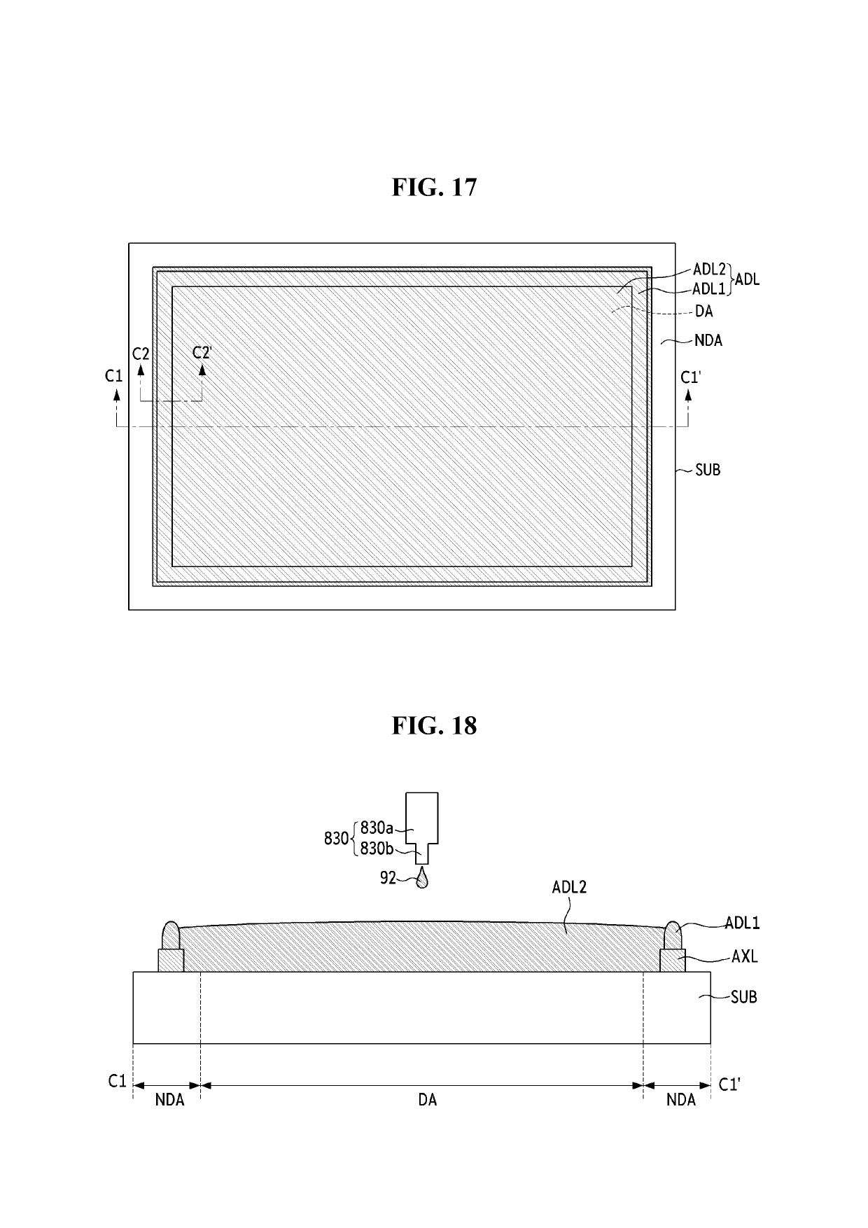

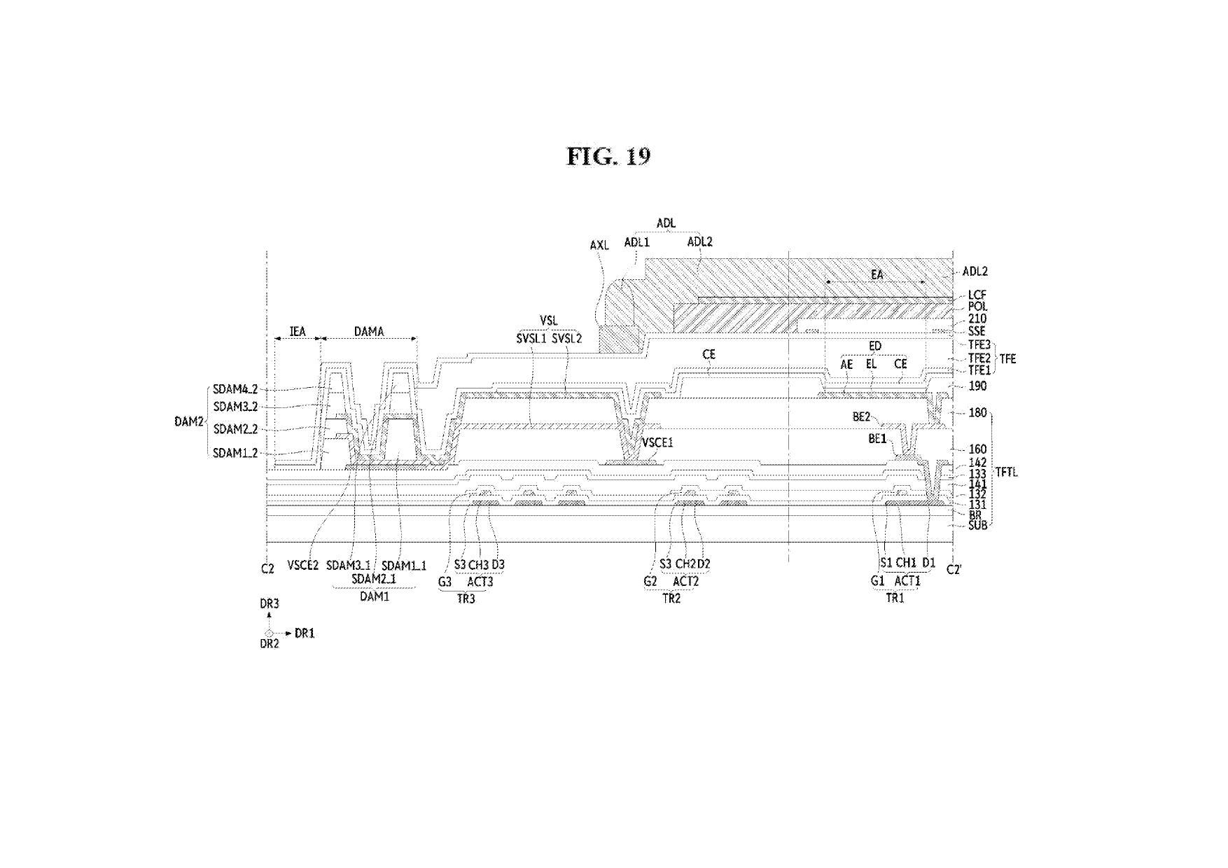

FIGS. 11, FIG. 12, FIG. 13, FIG. 14, FIG. 15, FIG. 16, FIG. 17, FIG. 18, and FIG. 19 are variously plan views and cross-sectional view to illustrate a method of providing (or manufacturing) a display device 10 according to an embodiment. For example, FIGS. 11 to 19 may be process drawings in manufacturing the display device 10 of FIG. 3 described above. Here, FIG. 12 is a cross-sectional view taken along line A1-A1’ of FIG. 11, FIG. 13 is a cross-sectional view taken along line A2-A2’ of FIG. 11, FIG. 15 is a cross-sectional view taken along line B1-B1’ of FIG. 14, FIG. 16 is a cross-sectional view taken along line B2-B2’ of FIG. 14, FIG. 18 is a cross-sectional view taken along line C1-C1’ of FIG. 17, and FIG. 19 is a cross-sectional view taken along line C2-C2’ of FIG. 17.

First, as shown in FIGS. 11, 12, and 13, a transistor layer TFTL may be formed (or provided) on a substrate SUB, a light emitting element layer including a light emitting element ED and a bank 190 may be formed on the transistor layer TFTL, and an encapsulation layer TFE may be formed on the light emitting element layer. The substrate SUB shown in FIGS. 11 and 12 may represent a stacked structure of all the layers of the substrate SUB to the encapsulation layer TFE, inclusive.

Then, a sensor electrode SSE may be formed in a display area DA of the substrate SUB, and an auxiliary layer AXL may be formed on a non-display area NDA of the substrate SUB. For example, the sensor electrode SSE may be disposed on the encapsulation layer TFE in the display area DA of the substrate SUB, and the auxiliary layer AXL may be disposed on the encapsulation layer TFE in the non-display area NDA of the substrate SUB. The auxiliary layer AXL may be spaced apart from the sensor layer and have a shape of a closed curve surrounding the display area DA. The sensor electrode SSE and the auxiliary layer AXL may be formed together with the same material, such as to be respective patterns of a same material layer (e.g., in a same layer as each other). However, the auxiliary layer AXL may have a greater thickness than the auxiliary layer AXL by being continuously laminated through an additional photolithography process. For example, after the sensor electrode SSE and a thickness portion of the auxiliary layer AXL are simultaneously formed by a photolithography process using a first mask, a conductive layer as an additional thickness portion may be selectively formed only on the thickness portion the auxiliary layer AXL by a photolithography process (e.g., an additional photolithography process) using a second mask. Thereafter, an insulating layer 210 of the sensor layer may be formed on the sensor electrodes SSE, a polarizing layer POL may be formed on the insulating layer 210, and a light control layer LCF may be formed on the polarizing layer POL.

Next, as shown in FIGS. 14, 15, and FIG. 16, a first adhesive layer ADL1 may be formed on the auxiliary layer AXL. For example, the first adhesive layer ADL1 may be formed by an inkjet printing device.

The inkjet printing device 830 may provide the first raw material 91 (e.g., resin or first adhesive material) of the first adhesive layer ADL1 by an inkjet printing method. The inkjet printing method is a non-contact patterning technology which may form a drop of several tens of micrometers (μm) at a desired location to create a pattern, and unlike other printing technologies, it has the advantage of having less adhesive consumption and drastically reducing the number of processes. The inkjet printing device 830 may discharge the first raw material 91 (e.g., resin) of the first adhesive layer ADL1 onto the substrate SUB by an inkjet printing method. The inkjet printing device 830 may include a head 830a and a nozzle 830b attached to the head 830a. The inkjet printing device 830 may discharge the first raw material 91 of the first adhesive layer ADL1 through the nozzle 830b. The first raw material 91 of the first adhesive layer ADL1 may be discharged onto the auxiliary layer AXL by the inkjet printing device. The first raw material 91 as an inkjet-printed first material on the auxiliary layer AXL may form a closed curve shape surrounding the display area DA. Then, the raw material of the first adhesive layer ADL1 on the auxiliary layer AXL is cured, so that the first adhesive layer ADL1 as an inkjet-printed-and-cured first material may be formed on the auxiliary layer AXL. The first adhesive layer ADL1 may be cured by at least one of ultraviolet rays, near-infrared rays, and heat.

Then, as shown in FIG. 17, FIG. 18, and FIG. 19, the second adhesive layer ADL2 may be formed using the inkjet printing device. For example, the second raw material 92 (e.g., resin or second adhesive material) of the second adhesive layer ADL2 may be discharged onto the encapsulation layer TFE, the polarizing layer POL, and the light control layer LCF by an inkjet printing device. For example, the second raw material 92 of the second adhesive layer ADL2 may be discharged onto the encapsulation layer TFE, the polarizing layer POL, and the light control layer LCF within a region defined by being surrounded by the first adhesive layer ADL1. The second raw material 92 as an inkjet-printed second material of the second adhesive layer ADL2 discharged onto the substrate may have a viscosity so as to spread toward the outer edge of the substrate SUB, that is, in a direction from the display area DA to the non-display area NDA.

At this time, the auxiliary layer AXL and the first adhesive layer ADL1 may function as a flow dam which prevents the second raw material 92 of the second adhesive layer ADL2 from spreading to the edge of the substrate SUB. Accordingly, the second raw material 92 of the second adhesive layer ADL2 may be prevented from flowing to the edge of the substrate SUB by a body including the auxiliary layer AXL together with the first adhesive layer ADL1. Then, the second raw material 92 of the second adhesive layer ADL2 discharged on the substrate SUB is cured, so that the second adhesive layer ADL2 as an inkjet-printed-and-cured second material may be formed on the encapsulation layer TFE, the polarizing layer POL, and the light control layer LCF. In this way, since the first adhesive layer ADL1 is formed first between the display area DA and the edge of the substrate SUB, and then the second adhesive layer ADL2 is formed, the spreading of an uncured adhesive material of the second adhesive layer ADL2 may be prevented by the stacked structure of the first adhesive layer ADL1 and the auxiliary layer AXL.

In an embodiment, a method for providing a display device includes providing a transistor layer TFTL in a display area DA of a substrate SUB, providing a light emitting element layer in the display area DA and electrically connected to the transistor layer TFTL, providing an encapsulation layer TFE on the light emitting element layer and in a non-display area NDA of the substrate SUB which is adjacent to the display area DA, and providing on the encapsulation layer TFE a first adhesive pattern (e.g., ADL1) which is in on the non-display area NDA, spaced apart from the display area DA and surrounds the display area DA (see, FIG. 14, for example), and a second adhesive pattern (e.g., ADL2) which is within a planar area surrounded by the first adhesive pattern. Here, the method may further include providing an auxiliary pattern between the encapsulation layer TFE and the first adhesive pattern, in the non-display area NDA of the substrate SUB, and providing a sensor electrode SSE between the encapsulation layer TFE and the second adhesive pattern, in the display area DA of the substrate SUB, where the auxiliary pattern and the sensor electrode may be respective portions of a same material layer on the encapsulation layer (e.g., in a same layer as each other).

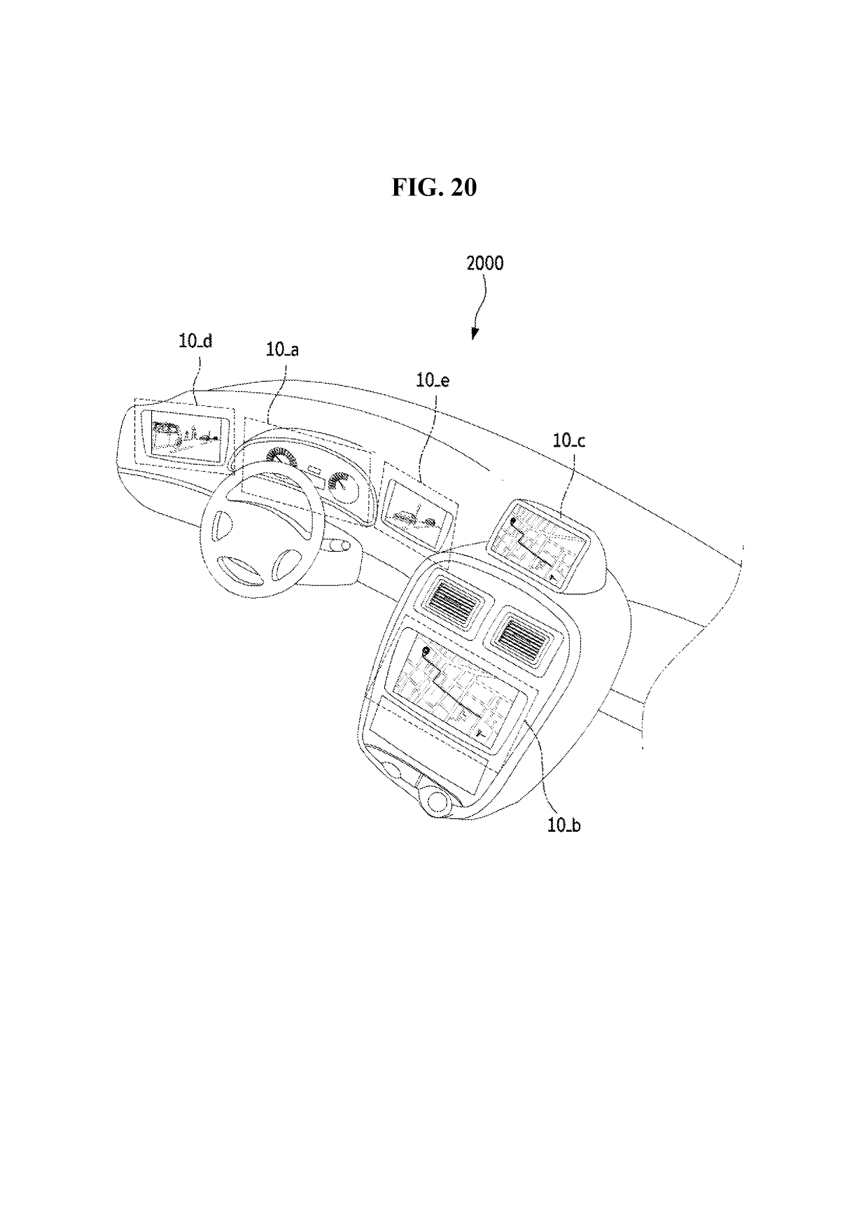

FIG. 20 is an exemplary drawing showing an instrument panel and center fascia of a vehicle as representing an electronic device 2000 including display devices 10_a, 10_b, 10_c, 10_d, and 10_e according to an embodiment. For example, FIG. 20 illustrates a vehicle to which display devices 10_a, 10_b, 10_c, 10_d, and 10_e according to an embodiment are applied.

Referring to FIG. 20, display devices 10_a, 10_b, and 10_c according to an embodiment may be applied to a dashboard of a vehicle, applied to a center fascia of a vehicle, or applied to a center information display (CID) disposed on a dashboard of the vehicle. Alternatively, display devices 10_d and 10_e according to an embodiment may be applied to a room mirror display replacing a side mirror of a vehicle.

At least one of the display devices 10_a, 10_b, 10_c, 10_d, and 10_e may have the same structure as the display device 10 of FIGS. 1 to 10 described above.

The display device 10 according to the embodiment can be applied to various electronic devices. The electronic device according to an embodiment includes the display device 10 described above and may further include modules or devices having additional functions in addition to the display device 10.

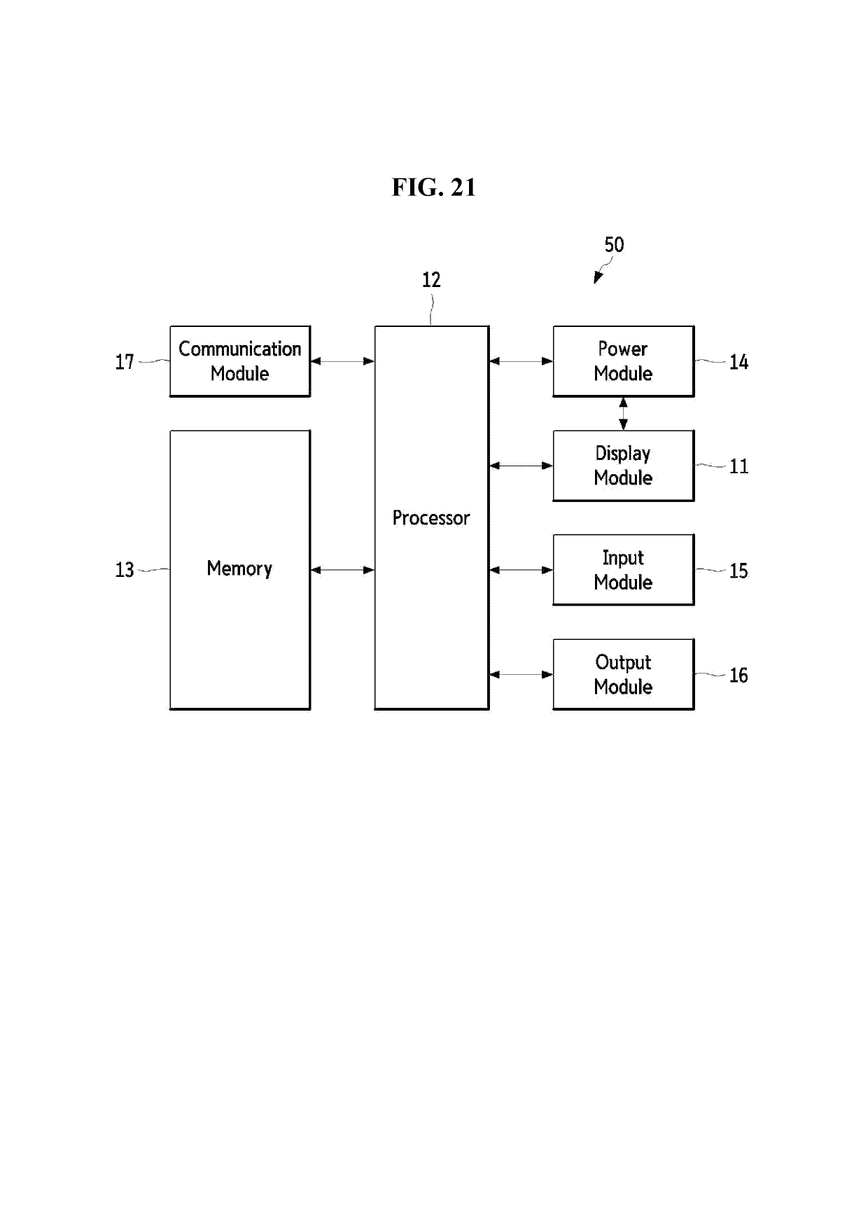

FIG. 21 is a block diagram of an electronic device 50 according to an embodiment. Referring to FIG. 21, the electronic device 50 according to an embodiment may include a display module 11, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module which converts the power supplied by the power supply module to generate power required for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module which is responsible for transmitting and receiving information between the electronic device 50 and an external device, and may include a receiving unit and a transmitting unit.

At least one of the components of the electronic device 50 described above may be included in the display device 10 according to the embodiments described above. In addition, some of the individual modules functionally included in one module may be included in the display device 10, and others may be provided separately from the display device 10. For example, the display device 10 includes a display module 11, and the processor 12, memory 13, and power module 14 may be provided in the form of other devices within the electronic device 11 other than the display device.

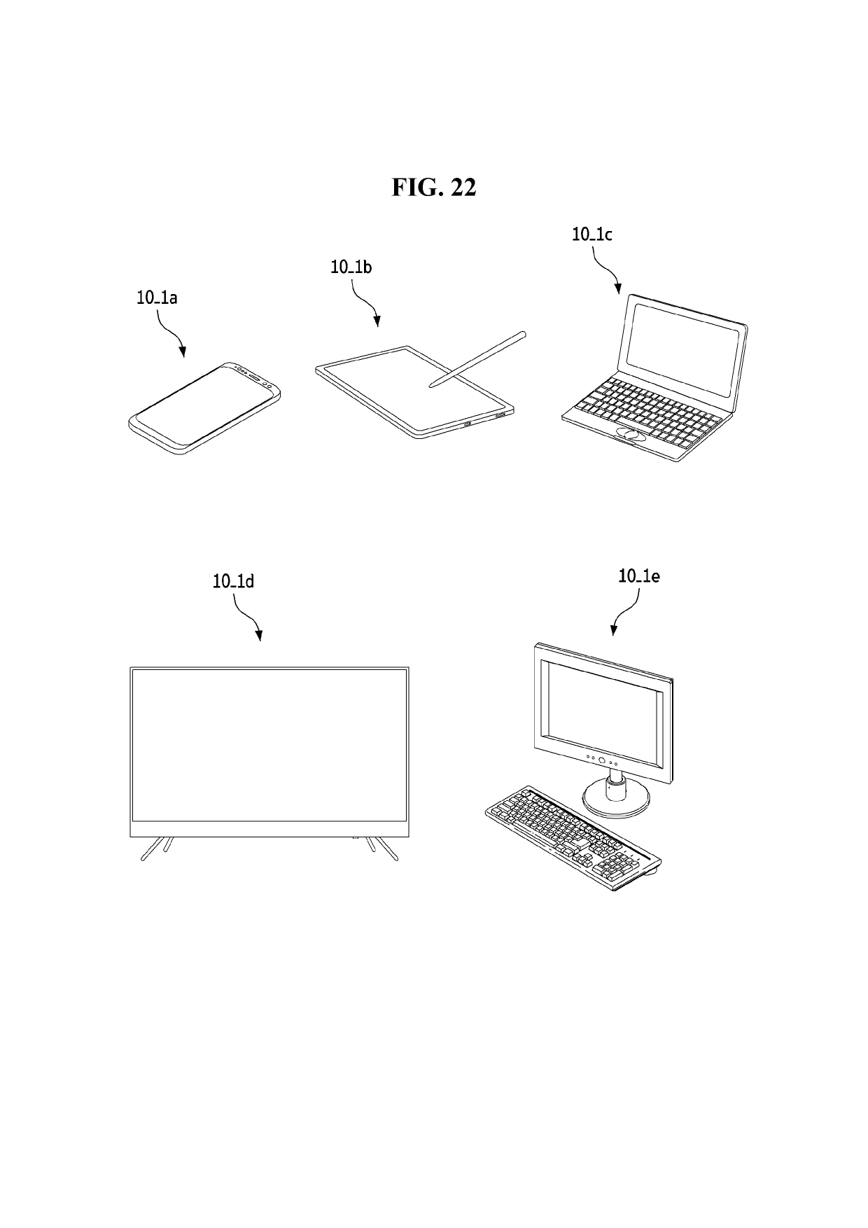

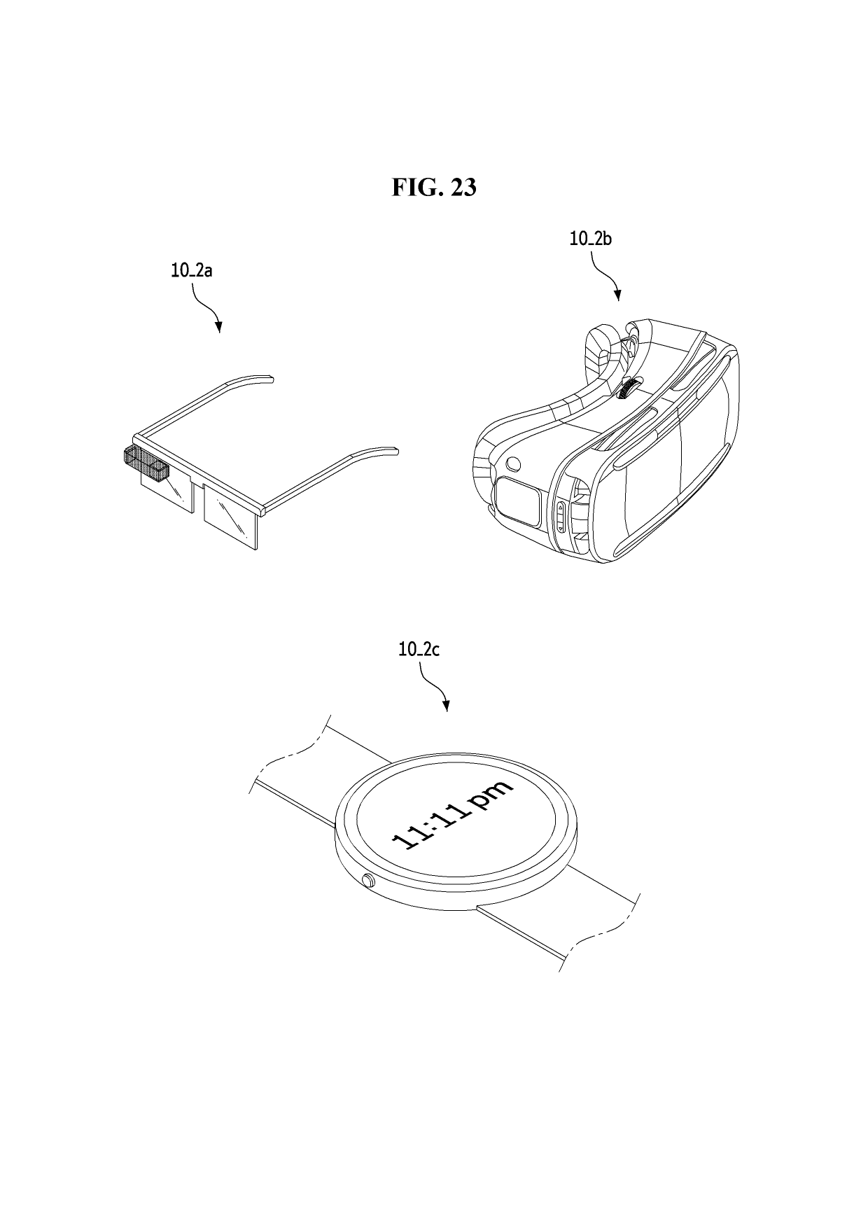

FIGS. 22 and 23 are schematic diagrams of electronic devices according to various embodiments. FIGS. 22 to 23 illustrate examples of various electronic devices to which the display device 10 according to the embodiments is applied.

FIG. 22 illustrates a smartphone 10_1a, a tablet PC 10_1b, a laptop 10_1c, a television (TV) 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

FIG. 23 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module which emits a display image and a reflector which reflects the emitted display screen and provides it to the user’s eyes, thereby providing a virtual reality or augmented reality screen to the user.

The smart watch 10_2c includes a biometric sensor as an input device, and may provide biometric information recognized by the biometric sensor to the user through the display module.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a substrate comprising a display area and a non-display area adjacent to each other;
a transistor layer in the display area;
a light emitting element layer in the display area and electrically connected to the transistor layer;
an encapsulation layer on the light emitting element layer and in the non-display area;
an auxiliary pattern which is on the encapsulation layer in the non-display area, and spaced apart from the display area; and
an adhesive layer on the encapsulation layer and the auxiliary pattern.

2. The display device of claim 1, further comprising a sensor electrode on the encapsulation layer, in the display area,
wherein the auxiliary pattern is in a same layer as the sensor electrode.

3. The display device of claim 2, wherein
the sensor electrode includes conductive layers stacked along a thickness direction of the substrate, and
the auxiliary pattern includes sub-auxiliary layers stacked along the thickness direction of the substrate.

4. The display device of claim 3, wherein the number of the conductive layers within the sensor electrode and the number of the sub-auxiliary layers within the auxiliary pattern are the same.
5. The display device of claim 4, wherein the sub-auxiliary layers within the auxiliary pattern are in same layers as the conductive layers within the sensor electrode, respectively.

6. The display device of claim 3, wherein
the conductive layers include a first conductive layer and a second conductive layer in order along the thickness direction from the encapsulation layer, and
the sub-auxiliary layers include:
a first sub-auxiliary layer in a same layer as the first conductive layer, the first sub-auxiliary layer having a first side closest to the display area and a second side which is opposite to the first side; and
a second sub-auxiliary layer which is in a same layer as the second conductive layer and includes patterns which are respectively at the first side and the second side of the first sub-auxiliary layer and spaced apart from each other along the first sub-auxiliary layer by a gap.

7. The display device of claim 6, wherein the second sub-auxiliary layer has a rectangular cross-section.

8. The display device of claim 3, wherein
the conductive layers include a first conductive layer, a second conductive layer and a third conductive layer in order along the thickness direction from the encapsulation layer, and
the sub-auxiliary layers include:
a first sub-auxiliary layer in a same layer as the first conductive layer;
a second sub-auxiliary layer in a same layer as the second conductive layer, the second sub-auxiliary layer having a first side closest to the display area and a second side which is opposite to the first side; and
a third sub-auxiliary layer which is in a same layer as the third conductive layer and includes patterns which are respectively at the first side and the second side of the second sub-auxiliary layer and spaced apart from each other along the second sub-auxiliary layer by a gap.

9. The display device of claim 8, wherein the third sub-auxiliary layer has a triangular cross-section.

10. The display device of claim 3, wherein
the conductive layers include a first conductive layer, a second conductive layer, a third conductive layer and a fourth conductive layer in order along the thickness direction from the encapsulation layer, and
the sub-auxiliary layers include:
a first sub-auxiliary layer in a same layer as the first conductive layer;
a second sub-auxiliary layer in a same layer as the second conductive layer;
a third sub-auxiliary layer in a same layer as the third conductive layer and having a first side closest to the display area and a second side which is opposite to the first side; and
a fourth sub-auxiliary layer which is in a same layer as the fourth conductive layer and includes patterns which are respectively at the first side and the second side of the third sub-auxiliary layer and spaced apart from each other along the third sub-auxiliary layer by a gap.

11. The display device of claim 10, wherein the third sub-auxiliary layer has a groove defined therein and open in a direction away from the encapsulation layer.

12. The display device of claim 10, wherein the patterns of the fourth sub-auxiliary layer have a semicircular cross-section.

13. The display device of claim 3, wherein
the conductive layers include a first conductive layer, a second conductive layer, a third conductive layer and a fourth conductive layer in order along the thickness direction from the encapsulation layer, and
the sub-auxiliary layers include,
a first sub-auxiliary layer in a same layer as the first conductive layer;
a second sub-auxiliary layer in a same layer as the second conductive layer;
a third sub-auxiliary layer in a same layer as the third conductive layer and having a first side closest to the display area and a second side which is opposite to the first side; and
a fourth sub-auxiliary layer which is in a same layer as the fourth conductive layer, the fourth sub-auxiliary layer disposed spaced apart from the second side of the third sub-auxiliary layer.

14. The display device of claim 13, wherein the third sub-auxiliary layer has an L-shaped cross-section.

15. The display device of claim 1, wherein
an edge of the adhesive layer which is furthest from the display area overlaps the auxiliary pattern, and
the adhesive layer extends continuously from the edge thereof to the encapsulation layer in the display area.

16. The display device of claim 1, further comprising a cover window on the adhesive layer,
wherein an upper surface of the adhesive layer which faces the cover window is curved in cross-section or straight in cross-section.

17. The display device of claim 1, wherein the auxiliary pattern has a cross-section of a square shape or a cross-section of a triangular shape.

18. An electronic device comprising:
a display device comprising:
a substrate comprising a display area and a non-display area adjacent to each other;
a transistor layer in the display area;
a light emitting element layer in the display area and electrically connected to the transistor layer;
an encapsulation layer on the light emitting element layer and in the non-display area;
an auxiliary pattern which is on the encapsulation layer in the non-display area, and spaced apart from the display area; and
an adhesive layer on the encapsulation layer and the auxiliary pattern.

19. A method for providing a display device, the method comprising:
providing a transistor layer in a display area of a substrate;
providing a light emitting element layer in the display area and electrically connected to the transistor layer;
providing an encapsulation layer on the light emitting element layer and in a non-display area of the substrate which is adjacent to the display area; and
providing on the encapsulation layer:
a first adhesive pattern which is in on the non-display area, spaced apart from the display area and surrounds the display area; and
a second adhesive pattern which is within a planar area surrounded by the first adhesive pattern.

20. The method of claim 19, further comprising:
providing an auxiliary pattern between the encapsulation layer and the first adhesive pattern, in the non-display area of the substrate; and
providing a sensor electrode between the encapsulation layer and the second adhesive pattern, in the display area of the substrate
wherein the auxiliary pattern and the sensor electrode are respective portions of a same material layer on the encapsulation layer.
